(19) United States
(12) Patent Application Publication
(10) Pub. No.: US 2025/0069926 A1
(43) Pub. Date: Feb. 27, 2025

(54) INTEGRATED SUBSTRATE PROCESSING SYSTEM WITH ADVANCED SUBSTRATE HANDLING ROBOT

(71) Applicant: Applied Materials, Inc., Santa Clara, CA (US)

(72) Inventors: Arunkumar Ramachandraiah, Bengaluru (IN); Paul Reuter, Austin, TX (US); Devendra Holeyannavar, Bangalore (IN); Steven Trey Tindel, Austin, TX (US); Dean Hruzek, Cedar Park, TX (US); Jeffrey Hudgens, San Francisco, CA (US); Maureen Breiling, Campbell, CA (US); Venkatesh Chinnaplar Rajappa, Bengaluru (IN); Micah E. Klaeser, San Jose, CA (US); Benjamin Johnston, Los Gatos, CA (US); Alton Wang, Taichung City (TW); Wei Siang Chao, Tainan City (TW); Chandrakant Sapkale, Bangalore (IN); Shiva Prasad Kota, Bengaluru (IN); Latha Ramesh, Bangalore (IN)

(21) Appl. No.: 18/236,554

(22) Filed: Aug. 22, 2023

(51) Int. Cl. H01L 21/677; B25J 11/00; G03F 7/00; H01L 21/67; H01L 21/687

(52) U.S. Cl. CPC H01L 21/67742; B25J 11/0095; G03F 7/70825; H01L 21/67167; H01L 21/68707

(57) ABSTRACT

Integrated substrate processing systems are disclosed that are able to achieve high-volume processing of substrates (e.g., greater than 120 substrates per hour) using environmentally sensitive processes and/or tools, such as photolithography processes and/or tools. In some embodiments, for example, the integrated substrate processing system may include an EFEM and a processing tool enclosure that are coupled together to form an integrated processing environment. The integrated substrate processing system may operate to maintain substantially uniform conditions (e.g., at a uniform temperature and relative humidity) throughout the integrated environment, and in some embodiments, may utilize an external air source, such as a remote air module (RAM), in order to do so. In some embodiments, high-volume processing of substrates may be further facilitated by employing specialized substrate handling robots and/or specially adapting the EFEM and/or processing tool enclosure.

### TECHNICAL FIELD

The present disclosure generally relates to the field of electronic device manufacturing and more particularly to systems, methods, and apparatuses for manufacturing electronic devices using environmentally sensitive processes.

### BACKGROUND

Photolithography is widely used in the manufacture of electronic devices, including semiconductor and display devices. Microlithography and nanolithography techniques, for example, may be used to create electrical features incorporated as part of such devices. Such lithography techniques typically involve the application of a light-sensitive photoresist to a surface of a substrate. A pattern generator may then expose selected areas of the light-sensitive photoresist with light, as part of a pattern, to cause chemical changes to the photoresist in the selected areas, preparing them for subsequent etching, deposition, or implantation processes which will form the electrical features. In order to continue to provide electronic devices to consumers at the prices consumers demand, new systems, methods, and apparatuses are needed for performing photolithography processes in high-volume substrate processing applications.

### BRIEF SUMMARY OF THE INVENTION

Embodiments of the present disclosure are directed toward an integrated substrate processing system adapted for high-volume processing of substrates using photolithography processes and/or tools (or other environmentally sensitive processes and/or tools). In some embodiments, for example, the integrated substrate processing system may include an EFEM and a processing tool enclosure that are coupled together to form an integrated processing environment. The integrated substrate processing system may operate to maintain the integrated processing environment at substantially uniform conditions throughout, and in some embodiments, may utilize an external air source, such as a remote air module (RAM), in order to do so.

In some embodiments, the integrated substrate processing system may employ one or more specialized substrate handling robots to rapidly move substrates between different locations within the integrated processing environment. In some embodiments, the substrate handling robots may utilize direct drive motors to affect end effector movement, which may allow for more rapid and precise movements than transmission-driven robots. In some embodiments, the substrate handling robots may be specially adapted to withstand the forces attendant to the rapid movement of substrates (e.g., enabled by the use of direct-drive motors). In some embodiments, for example, the substrate handling robots may be provided with end effectors having frictional grips or pads provided thereon, which may allow substrates to be secured by friction. Because substrate handling robots utilizing direct drive motors may produce smoother end effector movements (e.g., with less vibration), the substrate handling robots may be able to secure and transfer substrates by friction alone (e.g., withstanding up to 1 G of force during movement). Direct-drive robots, thus, can be used to transport substrates, using friction alone, faster and more reliably than with transmission-drive robots.

In some embodiments, the EFEM and processing tool enclosure of the integrated processing system may be adapted to help facilitate high-volume processing of substrates. In some embodiments, for example, the processing tool enclosure may be provided with one or more buffer stations that may facilitate efficient sequential processing of substrates (e.g., over multiple processing iterations or cycles). In some embodiments, for instance, the buffer stations may be positioned near a processing tool (e.g., near a movable stage thereof) and used to intermediately stage substrates so that substrates may be quickly transferred between the buffer stations and the processing tool, such that the amount of time spent to unload and load substrates from the processing tool may be minimized (e.g., allowing for processed substrates to be unloaded and new unprocessed substrates to be loaded in less than 10 seconds).

In some embodiments, for example, the integrated processing subsystem may be used to perform a method that involves transferring, by each of one or more substrate handling robots, a plurality of substrates from a movable stage of a processing tool to a plurality of buffer stations positioned near the movable stage, and a plurality of unprocessed substrates from the buffer stations to the movable stage. A photolithography process may then be performed on the plurality of unprocessed substrates with the processing tool. In some embodiments, each of the substrate handling robots may be used to transfer another plurality of unprocessed substrates from a substrate storage module to the buffer stations, for example, while the processing tool is performing the photolithography process on the plurality of unprocessed substrates.

### BRIEF DESCRIPTION OF THE DRAWINGS

The disclosure will be understood more fully from the detailed description below and from the accompanying drawings of various embodiments of the disclosure. The drawings are notably illustrative in nature and should not be taken to limit the disclosure to specific embodiments. Instead, the drawings should be considered broadly for the explanation and teachings that the drawings may provide.

FIG. 1A illustrates a perspective view of an integrated substrate processing system, in accordance with at least one embodiment of the present disclosure.

FIG. 1B illustrates a cross-sectional perspective view of an equipment front end module (EFEM) that may be used in the integrated substrate processing system of FIG. 1A, in accordance with at least one embodiment of the present disclosure.

FIG. 1C illustrates a perspective view of a substrate handling robot that may be used in the integrated substrate processing system of FIG. 1A, in accordance with at least one embodiment of the present disclosure.

FIG. 1D illustrates a side view of a processing tool enclosure that may be used in the integrated substrate processing system of FIG. 1A, in accordance with at least one embodiment of the present disclosure.

FIG. 1E illustrates a top cross-sectional view of a portion of the integrated substrate processing system of FIG. 1A, in accordance with at least one embodiment of the present disclosure.

FIGS. 2A-2B illustrate a rear cross-sectional view of a portion of a pair of buffer stations that may be used in an integrated substrate processing system, in accordance with at least one embodiment of the present disclosure.

FIG. 3 illustrates a number of different processing tools that may be used in an integrated substrate processing system, in accordance with at least one embodiment of the present disclosure.

FIG. 4 illustrates a flow diagram of an example method for processing substrates using an integrated substrate processing system, in accordance with at least one embodiment of the present disclosure.

FIG. 5 illustrates a block diagram of an example computer system in accordance with at least one embodiment of the present disclosure.

### DETAILED DESCRIPTION

In manufacturing an electronic device, a substrate may undergo a number of processing operations using a number of different processing tools. Photolithography processes, for example, are widely used in the manufacture of electronic devices, including semiconductor and display devices. Microlithography and nanolithography, for instance, may be used to create electrical features incorporated as part of such electronic devices. These lithography techniques typically involve the application of a light-sensitive photoresist to a surface of a substrate. A pattern generator may then expose selected areas of the light-sensitive photoresist with light, as part of a pattern, to cause chemical changes to the photoresist in the selected areas, preparing them for subsequent etching, deposition, or implantation processes which will form the electrical features.

In traditional electronic device manufacturing systems, a processing tool may be provided within a processing chamber, which may be arranged alongside other processing tools and chambers within a mainframe housing. Substrates may enter a processing chamber through one or more transfer and/or load lock chambers before being placed on a tool for processing. One or more robots, for example, may be used to transfer a substrate from a substrate carrier docked to an equipment front end module (EFEM), through one or more load lock and/or transfer chambers, into the processing chamber and onto the processing tool.

Some substrate processing operations and/or processing tools, however, are particularly sensitive to environmental conditions within a processing chamber. By way of example, a photolithography process or tool may call for a processing chamber to be maintained at a particular temperature (e.g., between 21-25° C. within ±0.5° C.), relative humidity (e.g., 50%±5%), pressure (e.g., between 0.06-0.12″ WC), and/or air flow rate or velocity (e.g., between 20-40 feet/minute). Existing electronic device manufacturing systems, however, are unable to maintain uniform or stable conditions within the processing chamber. In traditional electronic device manufacturing systems, for example, the environmental conditions within a processing chamber may be disrupted each time a substrate is passed from a load lock or transfer chamber, which may be maintained at very different conditions (i.e., as compared to the processing chamber). While restoring the processing chamber to the target conditions may be possible, doing so may take a significant amount of time. On account of the disruption and/or delay, high-volume processing of substrates using photolithography processes and/or tools (or other environmentally sensitive processes and/or tools) is not possible in existing electronic device manufacturing systems. Thus, in order to continue to provide electronic devices to consumers at the prices consumers demand, new systems, methods, and apparatuses are needed that allow for high-volume processing of substrates using photolithography processes and/or tools (or other environmentally sensitive processes and/or tools).

Embodiments of the present disclosure address the above-mentioned challenges in an integrated substrate processing system that is able to achieve high-volume processing of substrates (e.g., greater than 120 substrates per hour) using environmentally sensitive processes and/or tools, such as photolithography processes and/or tools. In some embodiments, for example, the integrated substrate processing system may include an EFEM and a processing tool enclosure that are coupled together to form an integrated processing environment. The integrated substrate processing system may operate to maintain the integrated environment at substantially uniform conditions throughout (e.g., at a uniform temperature and relative humidity throughout the EFEM and processing tool enclosure). The transfer of substrates from the EFEM (e.g., from one or more substrate storage modules provided in a substrate carrier coupled thereto) to the processing tool enclosure (and processing tool therein), thus, may be performed without disturbing the conditions within the integrated processing environment or delaying processing of the substrate by the processing tool, enabling high-volume substrate processing using environmentally sensitive processes and/or tools.

In some embodiments, for example, the integrated substrate processing system may utilize an external air source, such as a remote air module (RAM), to maintain uniform conditions within the integrated processing environment. In some embodiments, for instance, a remote air module (RAM) may be used to supply air to and, in some cases, remove (or exhaust) air from the EFEM and processing tool enclosure. In some embodiments, the RAM may operate to control a temperature and/or relative humidity of the air supplied to the EFEM and processing tool enclosure and/or control a rate at which air is supplied thereto and removed therefrom, which may help to control the conditions within the integrated processing environment. In some embodiments, air from the EFEM and/or processing tool enclosure may be removed (or exhausted) back to the RAM and or to an external environment (e.g., of a fabrication facility in which the integrated substrate processing system may be provided). In some embodiments, air from the EFEM and processing tool enclosure may be returned to the RAM in parallel, while in other embodiments, exhaust air from the EFEM and processing tool enclosure may be returned together. In some embodiments, for example, exhaust air from the EFEM may be provided to the processing tool enclosure and collectively returned with exhaust air from the processing tool enclosure to the RAM.

In some embodiments, the integrated substrate processing system may be designed to help control the pressure and air flow rate and/or velocity within the integrated processing environment. In some embodiments, for example, the EFEM and processing tool enclosure may be provided with one or more openings that allow for fluid communication therebetween, which may be designed (e.g., through their size, shape, and position) to help equalize air flow and/or maintain pressure balance within the integrated processing environment. In some embodiments, the rate at which air is supplied to and removed from the EFEM and processing tool enclosure may be independently adjusted (e.g., using flow control valves coupled to supply or exhaust vents thereof) to help equalize air flow and/or maintain pressure balance within the integrated processing environment.

In some embodiments, the integrated substrate processing system may be further adapted to facilitate high-volume processing of substrates. In some embodiments, for example, the integrated substrate processing system may include one or more specialized substrate handling robots that may be used to move substrates between different locations within the integrated processing environment. The substrate handling robots, for example, may be used to transfer substrates between the EFEM (e.g., to/from a substrate carrier coupled thereto) and the processing tool enclosure (e.g., to/from a processing tool therein). In some embodiments, the substrate handling robots may be capable of handling multiple substrates at the same time. The substrate handling robots, for example, may be provided with multiple end effectors, each of which may be capable of handling an individual substrate.

In some embodiments, the substrate handling robots may be adapted to move substrates rapidly between different locations. In some embodiments, for example, the substrate handling robots may utilize direct drive motors to affect end effector movement, which in general, may allow for more rapid and precise movements than transmission-based drive systems (e.g., belt-driven, chain-driven, or gear-driven systems). In some embodiments, the substrate handling robots may be able to perform relatively complex movements which may not be possible or performed as efficiently (e.g., as quickly as) in existing electronic device manufacturing systems using existing substrate handling robots. A substrate transfer process, for example, may be performed as a series of discrete movements, each having an associated settling time that may pass before the next movement proceeds (e.g., before vibrations associated with the movement are sufficiently attenuated). The substrate handling robots of the integrated substrate processing system may be able to affect a substrate transfer process in fewer movements than existing systems and robots (e.g., by eliminating and/or combining certain movements), reducing the overall transfer time (e.g., by reducing the total distance travelled and/or reducing the total amount of settling time).

In some embodiments, the substrate handling robots may be specially adapted to facilitate the rapid movement of substrates (e.g., enabled by the use of direct-drive motors) between locations in the integrated processing environment. For example, in some embodiments, the substrate handling robots may rely on friction to hold substrates in place during transit (e.g., atop end effectors thereof). In order to withstand forces that may be experienced during transit (e.g., up to 1 G of force when using direct-driven robots, as compared to a maximum of 0.3 G of force that may be sustained when using transmission-driven robots), the substrate handling robots may be provided with end effectors having suitable frictional properties. In some embodiments, for example, end effectors may be able to secure substrates with friction alone and may be provided with frictional grips or pads in order to do so. In some applications, end effectors may also have certain electrostatic discharge (ESD) properties, so that the end effectors may safely interface with the substrates. In some embodiments, for instance, the substrate handling robots may be provided with end effectors having frictional pads made of a perfluoroelastomeric compound (or FFKM) such as Perlast G90DM, a commercially available FFKM manufactured and sold by Precision Polymer Engineering, which may have frictional and ESD properties suitable for some applications.

In some embodiments, the processing tool enclosure of the integrated substrate processing system may be adapted to help facilitate high-volume processing of substrates. In some embodiments, for example, the processing tool enclosure may be provided with one or more buffer stations that may facilitate efficient sequential processing of substrates (e.g., over multiple processing iterations or cycles), allowing the integrated substrate processing system to achieve higher processing throughput than traditional electronic device manufacturing systems. In some embodiments, for instance, one or more buffer stations may be positioned near the processing tool and used to intermediately stage substrates so that the amount of time spent between processing iterations (e.g., to unload and load substrates from the processing tool) may be minimized. Transferring substrates between the substrate carrier and the processing tool before and after each processing iteration, for example, may take a relatively long period of time, as doing so may involve traversing a relatively long distance and performing a relatively complex series of movements (e.g., by a substrate handling robot). Instead, substrates can be quickly swapped between the buffer stations and processing tool between processing iterations (e.g., on account of a shorter and more direct path between the buffer station and processing tool) and transferred between the buffer stations and the substrate carrier during a previous or subsequent processing iteration (e.g., during which the substrate handling robots may otherwise be idle). In some embodiments, for example, the buffer stations may allow for the transfer of processed substrates from the processing tool to the buffer stations and the transfer of unprocessed substrates from the buffer stations to the processing tool in under 10 seconds.

In some embodiments, the EFEM may be adapted to help facilitate high-volume processing of substrates. In some embodiments, for example, the EFEM may help substrate handling robots to access different substrate storage modules provided in a substrate carrier. In some embodiments, for instance, a substrate carrier may include a number of substrate storage modules for storing substrates (e.g., before and after processing). But not all substrate storage modules may be directly accessible by each substrate handling robot in the EFEM. In some embodiments, the EFEM may be provided with a substrate exchange fixture that may allow substrates to be exchanged (or handed off) between substrate handling robots. A substrate handling robot, thus, may be able to indirectly access substrate storage modules (e.g., via another substrate handling robot) that the substrate handling robot would not be able to access otherwise. The substrate handling robots, thus, may be able to access, and the integrated substrate processing system may be able to process, a greater number of substrates before experiencing downtime (i.e., to replace the substrate storage modules).

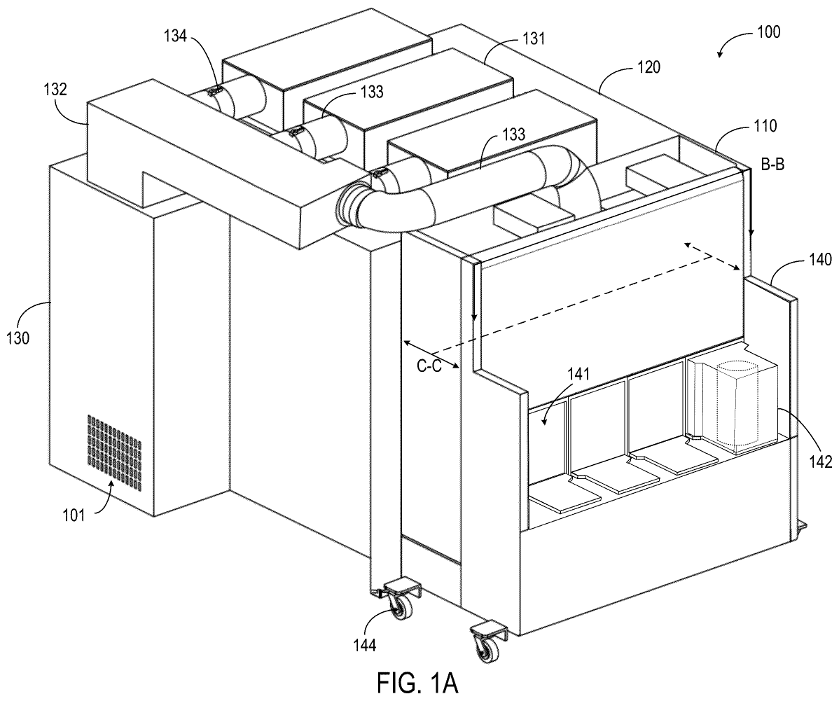

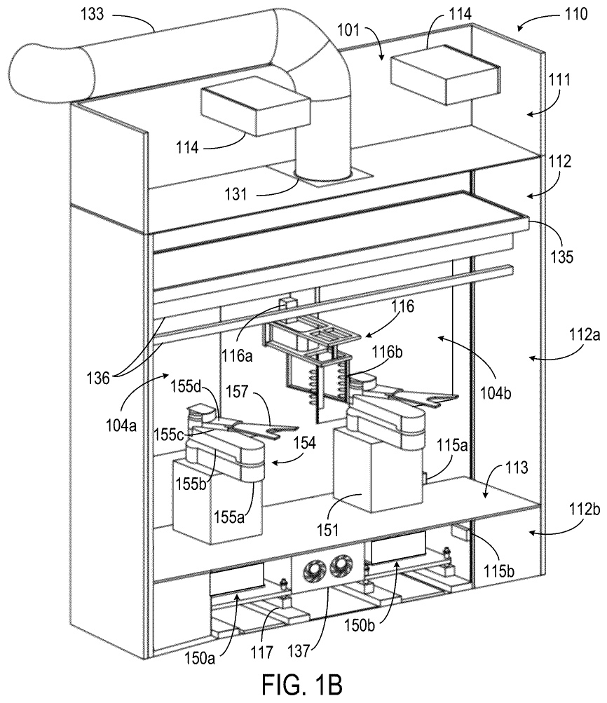

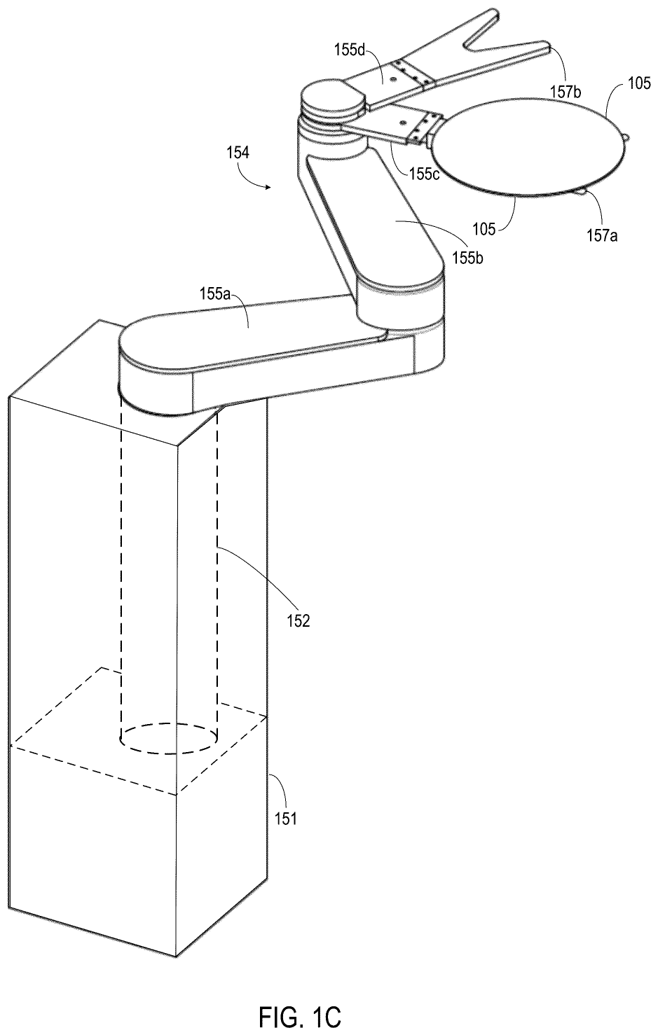

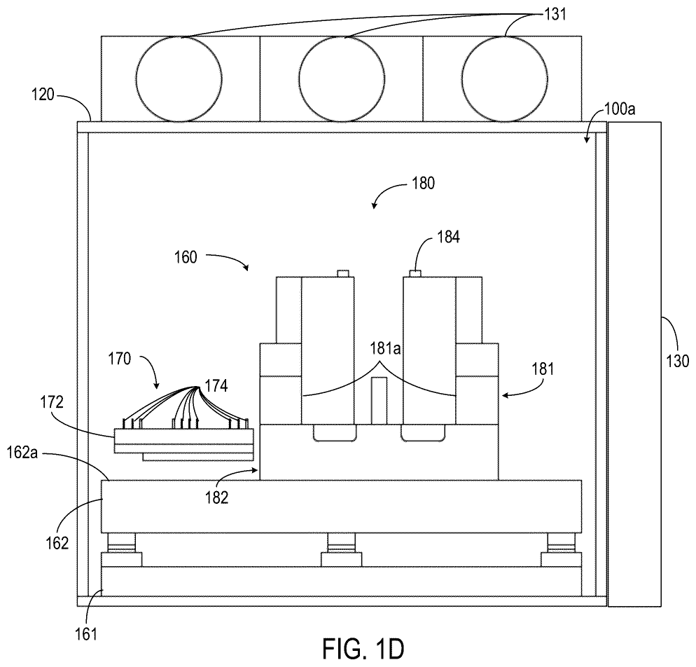

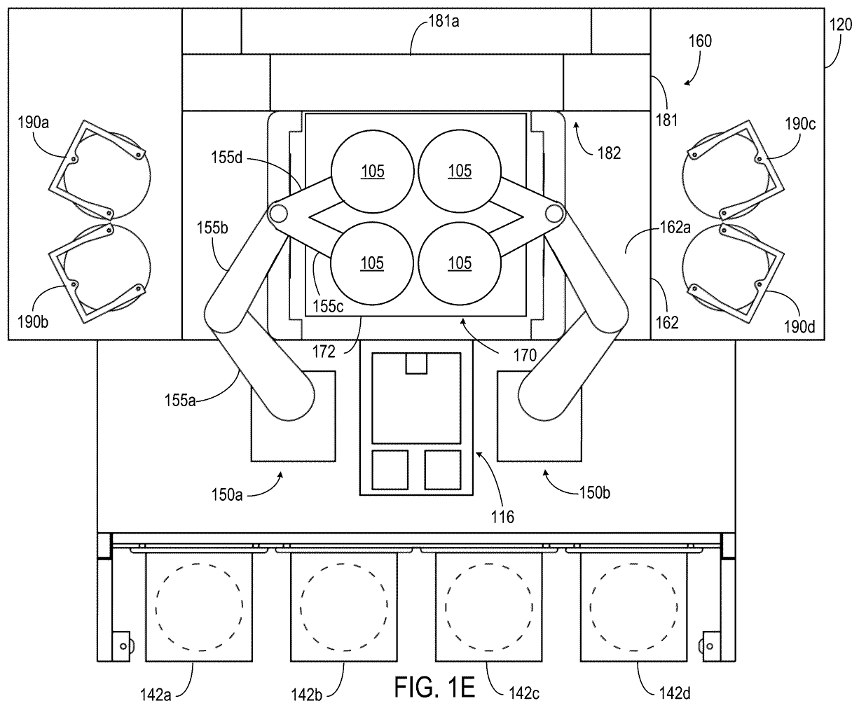

FIGS. 1A-1D (collectively FIG. 1) provide different views of an integrated substrate processing system 100 in accordance with at least one embodiment of the present disclosure. As illustrated in FIG. 1 and described in further detail below, the integrated substrate processing system 100 may include a substrate processing tool 160 (e.g., a digital lithography tool) that may be used to process one or more substrates 105 (e.g., to perform a photolithography process thereon). The processing tool 160 may be provided within a processing tool enclosure 120, which may be coupled to an equipment front end module (EFEM) 110 that may serve as a front-end interface to the processing tool 160. The EFEM 110 may include one or more substrate handling robots 150 that may be used to transfer substrates 105 between one or more substrate storage modules 142, provided in a substrate carrier 140 attached to the EFEM 110, and the processing tool enclosure 120 and processing tool 160.

In some embodiments, the EFEM 110 and processing tool enclosure 120 may be coupled together to form an integrated processing environment 100a. The integrated substrate processing system 100 may operate to maintain substantially uniform conditions throughout the integrated environment (i.e., throughout the EFEM 110 and processing tool enclosure 120), and in some embodiments, may utilize an external air source, such as a remote air module (RAM) 130, in order to do so (as described further herein). The integrated substrate processing system 100, for example, may maintain the integrated processing environment 100a at a particular temperature (e.g., between 21 and 25 degrees Celsius) and level of stability (e.g., within 0.05 degrees Celsius), and at a particular relative humidity (e.g., of between 45-55 percent). The transfer of substrates 105 from the EFEM 110 (e.g., from substrate storage modules 142 in substrate carrier 140) to the processing tool 160 in processing tool enclosure 120, thus, may be performed without disturbing the conditions within the integrated processing environment 100a or delaying processing of the substrates 105 by the processing tool 160, allowing the integrated substrate processing system 100 to achieve high processing throughput.

In some embodiments, the integrated substrate processing system 100 may be further adapted to facilitate high-volume processing of substrates 105. In some embodiments, for example, the integrated substrate processing system 100 may employ one or more specialized substrate handling robots 150 to quickly move substrates 105 (e.g., using one or more end effectors 157 thereof) between different locations within the integrated processing environment 100a. In some embodiments, for instance, the substrate handling robots 150 may utilize direct drive motors to affect end effector movement, which may allow for more rapid and precise movements than transmission-driven robots (e.g., belt-driven, chain-driven, or gear-driven robots). In some embodiments, the substrate handling robots 150 may also operate to perform complex movements in a more efficient manner than conventional robots (e.g., by eliminating and/or combining discrete movements performed by conventional robots). In some embodiments, the substrate handling robots 150 may be specially adapted to withstand the forces attendant to the rapid movement of substrates 105 (e.g., enabled by the use of direct-drive motors). In some embodiments, for example, the substrate handling robots 150 may be provided with end effectors 157 having frictional grips or pads provided thereon, which may allow substrates 105 to be secured by friction alone.

In some embodiments, the EFEM 110 and processing tool enclosure 120 may be adapted to help facilitate high-volume processing of substrates. In some embodiments, for example, the EFEM 110 may be provided with a substrate exchange fixture 116 that may allow substrates to be exchanged (or handed off) between substrate handling robots 150. A substrate handling robot 150, thus, may be able to indirectly access substrate storage modules 142 (i.e., via another substrate handling robot 150) that the substrate handling robot would not be able to access otherwise (e.g., where the substrate storage modules 142 are located beyond its direct reach). In some embodiments, the processing tool enclosure 120 may be provided with one or more buffer stations 190 that may facilitate efficient sequential processing of substrates (e.g., over multiple processing iterations or cycles). The buffer stations 190 may be positioned near the processing tool 160 and used to intermediately stage substrates 105 so that the amount of time spent between processing iterations (e.g., to unload and load substrates 105 from the processing tool 160) may be minimized. Substrates 105, for example, can be quickly swapped between the buffer stations 190 and processing tool 160 between processing iterations (e.g., on account of a shorter and more direct path between the buffer station 190 and processing tool 160) and transferred between the buffer stations 190 and the substrate carrier 140 during a previous or subsequent processing iteration (e.g., during which the substrate handling robots may otherwise be idle). Further detail regarding the integrated substrate processing system 100 and its components, as well as their function and operation, is provided below.

With reference to FIG. 1A, a perspective view of the integrated substrate processing system 100 is shown. As illustrated, integrated substrate processing system 100 may include an equipment front end module (EFEM) 110, a processing tool enclosure 120, a remote air module (RAM) 130, and a substrate carrier 140.

EFEM 110 and processing tool enclosure 120 may be coupled together to form an integrated processing environment 100a. EFEM 110 and processing tool enclosure 120, for example, may be coupled together such that an internal volume of EFEM 110 (e.g., of a main compartment 112 thereof) and an internal volume of processing tool enclosure 120 may be in fluid communication with one another. The EFEM 110 and processing tool enclosure 120 may be positioned adjacent to one another and may include one or more openings 104 (not shown in FIG. 1A) through adjacent walls thereof through which air may be able to flow (and substrates 105 may be passed). The EFEM 110 and processing tool enclosure 120 may generally be sealed (e.g., hermetically sealed) such that the processing environment 100a within EFEM 110 and processing tool enclosure 120 may be isolated from, and its conditions controlled independently of, an external environment 101 (e.g., of a fabrication facility in which the integrated substrate processing system 100 may reside).

In some embodiments, EFEM 110 and processing tool enclosure 120 may be removably coupled together, which may allow EFEM 110 to be coupled to different processing tool enclosures 120 (e.g., provided within a fabrication facility). In some embodiments, for example, the EFEM 110 may be provided with a set of wheels 144 that may allow EFEM 110 to be moved between and couple to different processing tool enclosures 120. The EFEM 110, for instance, may be moved into position with respect to a particular processing tool enclosure 120 (e.g., such that the one or more openings 104 on adjacent walls thereof are aligned) and the EFEM 110 and processing tool enclosure 120 may be secured together, for example, using one or more latches (or other mechanical coupling mechanism). In some embodiments, the EFEM 110 and/or processing tool enclosure 120 may be provided with one or more alignment guides that may facilitate alignment of the EFEM 110 and processing tool enclosure 120 during the coupling process. In some embodiments, the openings 104 in EFEM 110 and/or processing tool enclosure 120 may be provided with a gasket (or similar feature) to facilitate a sealed coupling therebetween.

In some embodiments, the integrated substrate processing system 100 may operate to maintain substantially uniform conditions within the integrated processing environment 100a. That is, in some embodiments, integrated substrate processing system 100 may control the environmental conditions within EFEM 110 and processing tool enclosure 120 such that the environmental conditions may be substantially uniform throughout (e.g., throughout an internal volume of EFEM 110 and an internal volume of processing tool enclosure 120). Substrate processing system 100, for instance, may maintain the integrated processing environment 100a at conditions suitable for performing a photolithography process. By way of example, substrate processing system 100 may operate to maintain the processing environment 100a at a particular temperature (e.g., between 21-25° C. within ±0.5° C.) and/or relative humidity (e.g., 50%±5%). In some cases, substrate processing system 100 may also operate to control a pressure (e.g., between 0.06-0.12″ WC) and/or an air flow rate or velocity (e.g., between 20-40 feet/minute) within the processing environment 100a.

In some embodiments, for example, the integrated substrate processing system 100 may utilize an external air source to help maintain uniform conditions within the integrated processing environment 100a. In some embodiments, for instance, the integrated substrate processing system 100 may include a remote air module 130 that may be used to help control the environmental conditions within the integrated processing environment 100a (i.e., within EFEM 110 and processing tool enclosure 120). In some embodiments, for example, remote air module 130 may be used to supply air to and, in some cases, remove (or exhaust) air from EFEM 110 and processing tool enclosure 120. Remote air module 130, for instance, may draw air from external environment 101 and condition the air (e.g., to a particular temperature and relative humidity) before supplying the air to the integrated processing environment 100a. Air within the integrated processing environment 100a, in turn, may be exhausted back to the remote air module 130 and/or to external environment 101 (e.g., of a fabrication facility in which the integrated substrate processing system 100 may be provided). Where air is exhausted back to remote air module 130, the air may be recirculated (e.g., in a closed loop), for example, after being appropriately re-conditioned, discharged to the external environment 101 (e.g., in an open loop), or both (e.g., in a semi-closed loop).

In some embodiments, remote air module 130 may supply air through one or more supply vents 131 provided in EFEM 110 and processing tool enclosure 120 (e.g., on a top surface thereof). In some embodiments, for example, remote air module 130 may be coupled to supply vents 131 via one or more supply manifolds 132 and air ducts 133 and may supply air therethrough. In some embodiments, remote air module 130 may be coupled to supply vents 131 using one or more adjustable valves 134, which may be used to adjust a flow rate and/or velocity of air supplied through respective supply vents 131.

In some embodiments, air from EFEM 110 and/or processing tool enclosure 120 may be removed (or exhausted) through one or more exhaust vents (not shown), which for example, may be provided on an outer wall thereof (e.g., toward a bottom of a lateral wall thereof). In some embodiments, remote air module 130 may operate to remove (or exhaust) air through the one or more exhaust vents provided in EFEM 110 and/or processing tool enclosure 120. In some embodiments, for example, remote air module 130 may be coupled to the exhaust vents provided in EFEM 110 and/or processing tool enclosure 120 via one or more return manifolds and air ducts and may draw exhaust air therethrough.

In some embodiments, exhaust air from EFEM 110 and processing tool enclosure 120 may be returned to remote air module 130 in parallel (e.g., flowing from exhaust vents provided in EFEM 110 and processing tool enclosure 120 directly to remote air module 130). In other embodiments, exhaust air from EFEM 110 may be provided to processing tool enclosure 120 and may be collectively returned with exhaust air from processing tool enclosure 120 to return air module 130. In some embodiments, for example, an exhaust port may be provided in adjacent walls of EFEM 110 and processing tool enclosure 120 (e.g., toward a bottom thereof) through which air may flow from EFEM 110 to processing tool enclosure 120. In some embodiments, EFEM 110 may include an exhaust fan 137 (as shown in FIG. 1C) that may operate to push air from EFEM 110 into processing tool enclosure 120. The exhaust air from EFEM 110 along with exhaust air from within processing tool enclosure 120 may then be collectively exhausted from processing tool enclosure 120 through exhaust vents provided in processing tool enclosure 120.

In some embodiments, air from EFEM 110 and/or processing tool enclosure 120 may be exhausted to an external environment 101. In some embodiments, for example, air from EFEM 110 may be exhausted to external environment 101 while air from processing tool enclosure 120 is exhausted to remote air module 130 (as described above), or vice versa. In some embodiments, for instance, an exhaust port may be provided in a floor of EFEM 110, which may be set off from a floor of external environment 101 (e.g., on a set of wheels 144), and air may be exhausted to external environment 101 therethrough.

In some embodiments, remote air module 130 may help to control a temperature and/or relative humidity within the integrated processing environment 100a. In some embodiments, for instance, remote air module 130 may operate to control a temperature and/or relative humidity of the air supplied to EFEM 110 and processing tool enclosure 120. In some embodiments, for instance, remote air module 130 may include a refrigeration and heating system that may be used to control air temperature and/or relative humidity. The refrigeration system, for example, may lower a temperature of inlet air below a saturation point (e.g., below 10° C.) such that condensation occurs, reducing a relative humidity of the air (e.g., to a particular level). The heating system may then raise the temperature of the air (e.g., to a particular level).

In some embodiments, remote air module 130 may help to control a pressure and air flow rate and/or velocity within the integrated processing environment 100a. In some embodiments, for instance, remote air module 130 may operate to control a rate at which air is supplied to and removed (or exhausted) from EFEM 110 and processing tool enclosure 120. In some embodiments, for example, remote air module 130 may operate to circulate air at a particular rate. In some embodiments, remote air module 130 may be able to adjust the rate at which air is circulated (e.g., based on a volume of the integrated processing environment 100a). As an illustrative example, in some embodiments, remote air module 130 may be able to circulate air at up to 30 cubic meters per minute (or CMM).

In some embodiments, the integrated substrate processing system 100 may be designed to help control the pressure and air flow rate and/or velocity within the integrated processing environment 100a. In some embodiments, for example, the openings 104 provided between the EFEM 110 and processing tool enclosure 120 may be designed (e.g., through their size, shape, and position) to help equalize air flow and/or maintain pressure balance within the integrated processing environment (e.g., between EFEM 110 and processing tool enclosure 120). In some embodiments, the number of vents (e.g., supply and/or exhaust vents) provided in EFEM 110 and processing tool enclosure 120 and their location may be chosen (e.g., based on a relative internal volume of each) to help equalize air flow and maintain pressure balance within the integrated processing environment 100a. As illustrated in FIG. 1A, for example, EFEM 110 may be provided with a single air supply vent 131 and processing tool enclosure 120 may be provided with three air supply vents 131 (e.g., with an internal volume of processing tool enclosure 120 being roughly three times as large as that of EFEM 110).

In some embodiments, the rate at which air is supplied to and removed from the EFEM 110 and processing tool enclosure 120 may be independently adjusted to help equalize air flow and/or maintain pressure balance within the integrated processing environment 100a. In some embodiments, for instance, one or more supply vents 131 or exhaust vents may be coupled to remote air module 130 using flow control valves 134 (or similar feature), which may be used to control the amount of air flowing therethrough. By way of example, as illustrated in FIG. 1A, valves 134a-c may permit air flow at up to 6 CMM and valve 134d may permit air flow at 7 CMM (e.g., based on a relative interval volume of the processing tool enclosure 120 and EFEM 110). In some embodiments, flow control valves 134 may be manually adjusted to a particular flow rate, while in others, flow control valves 134 may be automatically adjusted (e.g., using a system controller).

In some embodiments, the integrated substrate processing system 100 may include one or more sensors that may be used to help monitor the state of the integrated processing environment 100a. In some embodiments, for example, the integrated substrate processing system 100 may include one or more sensors distributed at various locations within the integrated processing environment 100a that may measure a temperature, relative humidity, pressure and/or air flow rate or velocity within the environment. In some embodiments, the sensor measurements may be used to control operation of the remote air module 130. In some embodiments, for instance, the sensor measurements may be provided to a controller of the remote air module 130, which may process the sensor measurements and adjust the operation of remote air module 130 accordingly. In some embodiments, the sensor measurements may be provided to a system controller (e.g., of the integrated substrate processing system 100), which may process the sensor measurements and adjust the operation of remote air module 130 accordingly (e.g., by transmitting a control signal thereto).

In some embodiments, a substrate carrier 140 may be coupled to (or formed as part of) the EFEM 110 and may be used to store substrates 105, for example, before and/or after being processed by processing tool 160. As illustrated in FIG. 1A, for example, substrate carrier 140 may be coupled to the front of EFEM 110 (e.g., at a wall opposite of processing tool enclosure 120). The substrate carrier 140 may include one or more substrate storage modules 142 (e.g., substrate storage modules 142a-142d), each of which may be able to safely store a number of individual substrates 105 (e.g., up to 25 substrates). Each substrate storage module 142, for example, may provide a number of slots (e.g., formed by vertically stacked fins) in which a substrate 105 may be stored (e.g., horizontally). In some embodiments, for example, the substrate storage modules 142 may be or include a front opening unified pod (FOUP), a substrate cassette, or the like.

The configuration of substrate storage modules 142 may vary depending on the embodiment and its application, for example, providing for different numbers of slots (e.g., 10 slots, 25 slots, etc.) and/or accommodating substrates 105 of different shape, size, and/or thickness. The slot pitch (e.g., space between fins) of a substrate storage module 142, for example, may vary depending on the embodiment (e.g., depending on the maximum thickness of the substrates 105 expected to be stored). By way of example, in some embodiments, substrate storage modules 142 may have a slot pitch of between 5-6 mm, which may be used to store substrates 105 having a thickness of 2 mm±2 mm (e.g., to account for variations due to warpage). In some embodiments, the substrate storage modules 142 may be designed to facilitate the transfer of substrates 105 therefrom and thereto, for example, by one or more substrate handling robots 150 provided within EFEM 110 (not shown in FIG. 1A). The substrate handling robots 150, for example, may be able to access substrate storage modules 142 through one or more openings 141 in EFEM 110 (e.g., using end effectors 157 to gather or deposit substrates 105 from or to slots therein).

Turning now to FIG. 1B, a cross-sectional perspective view of an EFEM 110 that may be used in the integrated substrate processing system 100 is shown (e.g., taken along B-B of FIG. 1A). As illustrated, EFEM 110 may include a main compartment 112 and an upper compartment 111 provided there above. The upper compartment 111 may be open to an external environment 101 (e.g., of a fabrication facility in which the integrated substrate processing system 100 may be provided) and may be used to secure different components of the EFEM 110. In some embodiments, for example, upper compartment 111 may be used to secure one or more controllers 114, which may be used to control operation of various components within EFEM 110 (e.g., for controlling operation of substrate handling robots 150).

Main compartment 112 may be coupled to a processing tool enclosure 120 to form an integrated processing environment 100a therewith. For instance, as illustrated in FIG. 1B, main compartment 112 may be provided with a pair of openings 104 (e.g., openings 104a, 104b) that may interface with corresponding openings provided in processing tool enclosure 120 and allow for fluid communication therebetween. The main compartment 112 may generally be sealed (e.g., hermetically sealed) off from upper compartment 111 and from external environment 101, more broadly, such that the integrated processing environment (i.e., formed between main compartment 112 and processing tool enclosure 120) may be isolated therefrom, and its conditions controlled independently thereof. The integrated substrate processing system 100 may operate to control the conditions within the main compartment 112, for example, to maintain uniform conditions throughout the integrated processing environment 100a (e.g., throughout the main compartment 112 and processing tool enclosure 120). In some embodiments, an external air source, such as a remote air module 130, may be used to help control the conditions within main compartment 112. In some embodiments, for example, remote air module 130 may operate to circulate air through main compartment 112.

By way of example, in some embodiments, an air duct 133 may be received within upper compartment 111 and may be coupled to a supply vent 131 provided in a wall between upper compartment 111 and main compartment 112. Remote air module 130 may be coupled to air duct 133 and may operate to supply air to main compartment 112 through supply vent 131. Air entering main compartment 112 at supply vent 131 may flow downward and pass through a particle filter and diffuser 135, which may filter the incoming air to remove particles therefrom (e.g., particles larger than a particular size) and diffuse the air, resulting in unidirectional laminar airflow thereafter (e.g., to the rest of main compartment 112 there below). In traditional electronic device manufacturing systems, a fan is typically provided within the EFEM to push air through a filter (e.g., as part of a fan filter unit). The inclusion of such a fan, however, introduces vibration dynamics into the system (i.e., as a result of its operation). By employing a remote air module 130, such a fan may be eliminated and the integrated substrate processing system 100 may be able to avoid the issues attendant to its use.

After exiting the particle filter and diffuser 135, air may pass over (or through) an ionization device 136, which may operate to neutralize the air flowing there past (or therethrough). In some embodiments, for instance, the ionization device 136 may be a high-precision ionization system comprising one or more ionization bars. The performance of the ionization device 136 may be characterized in terms of a voltage decay, for example, an amount of time taken for a voltage produced by the ionization device to decay from an upper to a lower level.

After passing over (or through) ionization device 136, air may continue to flow downwards past openings 104. Openings 104 may provide an interface between main compartment 112 and processing tool enclosure 120 through which substrates 105 may be passed. Because the air flowing past openings 104 has been neutralized (e.g., by ionization device 136), the air may safely interact with substrates 105 passing therethrough.

Air may continue downward toward a lower portion 112b of main compartment 112. Air may be exhausted from lower portion 112b, for example, back to remote air module 130 (either directly or indirectly through processing tool enclosure 120) or to external environment 101. In some embodiments, for example, one or more exhaust vents may be provided in a wall of the lower portion 112b of main compartment 112, which may be coupled to remote air module 130 and through which air may be directly exhausted to remote air module 130. In other embodiments (e.g., as illustrated in FIG. 1B), air in the lower portion 112b of main compartment 112 may be passed to processing tool enclosure 120, whereafter the air may be collectively exhausted to return air module 130 (i.e., along with exhaust air from processing tool enclosure 120). In some embodiments, for example, an exhaust port may be provided in a wall of the lower portion 112b of main compartment 112 (and processing tool enclosure 120), through which air may flow to processing tool enclosure 120. In some embodiments, an exhaust fan 137 may be provided in the lower portion 112b of main compartment 112, which may be coupled to the exhaust port and may operate to push air into processing tool enclosure 120, whereafter the air may be collectively exhausted to return air module 130. In some embodiments, the lower portion 112b of main compartment 112 may be separated from an upper portion 112a by a screen or diffuser 113 through which air may pass. The diffuser 113 may separate the laminar air flow within upper portion 112a from the exhaust fan air flow within lower portion 112b, which may allow for better control of the conditions (e.g., more uniform and/or stable) within the integrated processing environment 100a.

In some embodiments, the EFEM 110 may include one or more probes or sensors 115, for example, within main compartment 112, to help monitor the conditions within the EFEM 110 and integrated processing environment 100a. In some embodiments, for example, the sensors 115 may measure a temperature, relative humidity, pressure, air flow rate or velocity, or other condition within the EFEM 110 and integrated processing environment 100a. In some embodiments, for example, the EFEM 110 may include a sensor 115a that may be used to measure a pressure within the EFEM 110. The pressure sensor 115a may be a differential pressure sensor, which may be positioned between the upper portion 112a and lower portion 112b of main compartment 112 and may measure a pressure difference therebetween. In some embodiments, the EFEM 110 may include a probe or sensor 115b that may measure a temperature and/or relative humidity within the EFEM 110 and integrated processing environment 100a. In some embodiments, for example, a temperature and/or relative humidity sensor 115b may be mounted within a lower portion 112b of the main compartment 112 of EFEM 110. The above example(s) are merely illustrative and additional sensors 115 may be provided within EFEM 110 and/or located at different positions therewithin.

In some embodiments, the sensors 115 may continuously provide measurements (e.g., as an analog or digital signal) to one or more controllers, which may process the measurements to adjust operation of the integrated substrate processing system 100. In some embodiments, for example, the sensors 115 may provide measurements to a system controller, which may process the sensor measurements and adjust operation of different system components accordingly. The system controller, for example, may process the sensor measurements and adjust operation of the remote air module 130, flow control valves 134, substrate handling robots 150, processing tool 160, and/or other components of the integrated substrate processing system 100 (e.g., by transmitting a control signal thereto). In some embodiments, the sensor measurements may be provided to the components themselves (e.g., to a controller of the remote air module 130, flow control valves 134, substrate handling robots 150, processing tool 160, etc.), which may process the sensor measurements and adjust their operation accordingly.

Main compartment 112 may house one or more substrate handling robots 150 (e.g., a pair of substrate handling robots 150a, 150b). In some embodiments, the substrate handling robots 150 may be secured to the EFEM 110, for example, to a support bracket 117 provided on a floor of main compartment 112 (e.g., within lower portion 112b). The substrate handling robots 150 may be used to move substrates 105 between different locations within the integrated processing environment 100a. The substrate handling robots 150, for example, may be used to transfer substrates 105 between substrate carrier 140 (e.g., from/to slots in substrate storage modules 142 thereof), processing tool 160 (e.g., to/from stage 170 thereof), and/or buffer stations 190 (e.g., to/from slots therein). The substrate handling robots 150, for instance, may be able to access substrate storage modules 142 through openings 141 in EFEM 110 and processing tool 160 and/or buffer stations 190 through openings 104 in EFEM 110.

In some embodiments, the substrate handling robots 150 may include one or more end effectors 157, each of which may be used to transfer an individual substrate 105. By way of example, as illustrated in FIG. 1, each substrate handling robot 150a, 150b may include a pair of end effectors 157a, 157b, allowing for the simultaneous transfer of up to four substrates 105. In some embodiments, end effectors 157 may be provided at a terminal end (or terminal ends) of an articulating linkage 154 that may be movably coupled to an extendable support shaft 152. The articulating linkage 154 may be manipulated to move end effectors 157 between different positions in a horizontal plane, and the support shaft 152 may be raised and lowered to raise and lower end effectors 157 (and articulating linkage 154) in a vertical direction. Through manipulation of the articulating linkage 154 and adjustment of support shaft 152, end effectors 157 may be able to transfer substrates 105—e.g., gather (or pick up), carry (or hold), and deposit (or set down) substrates 105—between different locations within the integrated processing environment 100a.

In some embodiments, the substrate handling robots 150 may be adapted to rapidly move substrates 105 between different locations. In some embodiments, for example, the articulating linkage 154 of substrate handling robots 150 may utilize direct drive motors to affect movement of end effectors 157, which in general, may allow for more rapid and precise end effector movement than transmission-based drive systems (e.g., belt-driven, chain-driven, or gear-driven systems). In some embodiments, the substrate handling robots 150 may be able to perform relatively complex movements which may not be possible or performed as efficiently (e.g., as quickly as) in existing electronic device manufacturing systems using existing substrate handling robots. A substrate transfer process, for example, may be performed as a series of discrete movements, each of which may have an associated settling time that may pass before the next movement proceeds (e.g., before vibrations associated with the movement are sufficiently attenuated). The substrate handling robots 150 of the integrated substrate processing system 100 may be able to affect a substrate transfer process in fewer movements than existing systems and robots (e.g., by eliminating and/or combining certain movements), reducing the overall transfer time (e.g., by reducing the total distance travelled and/or the total amount of settling time).

In some cases, each substrate handling robot 150 may not be able to access all locations within the integrated processing environment 100a, for example, where the locations are beyond the reach of articulating linkage 154 and end effectors 157 thereof. Each substrate handling robot 150, for example, may not be able to access each substrate storage module 142 in the substrate carrier 140, the entire stage 170 of processing tool 160, or each buffer station 190. For instance, as illustrated in FIG. 1E, substrate handling robot 150a may not be able to access substrate storage modules 142c, 142d or buffer stations 170c, 170d. Similarly, substrate handling robot 150b may not be able to access substrate storage modules 142a, 142b or buffer stations 170a, 170b. In some embodiments, the substrate handling robots 150 may be able to exchange substrates 105 between each other, effectively extending the reach of each substrate handling robot, for example, allowing each substrate handling robot 150 to access each substrate storage module 142, the entire stage 170 of processing tool 160, and/or each buffer station 190.

In some embodiments, for example, EFEM 110 may be provided with a substrate exchange fixture 116 (e.g., within main compartment 112) that may be used to facilitate the exchange of substrates 105 between substrate handling robots 150. In some embodiments, the substrate exchange fixture 116 may include a pre-aligner element 116a and one or more pass-through slots 116b. The pre-aligner element 116a may be able to receive a substrate 105 from a first substrate handling robot 150 (e.g., from substrate handling robot 150a) and may facilitate alignment of the substrate 105 (e.g., to a particle radial orientation) upon receipt. A second substrate handling robot 150 (e.g., substrate handling robot 150b) may then retrieve the substrate 105 from the pre-aligner element 116a. In some embodiments, the pre-aligner element 116a may be used when transferring substrates 105 from substrate carrier 140 (e.g., from a particular substrate storage module 142) for placement on stage 170 of processing tool 160, as the pre-aligner element 116a may help to ensure that the substrate 105 is in a particular orientation when retrieved by second substrate handling robot 150 such that the substrate 105 may be placed on processing tool 160 (e.g., on a stage 170 thereof) in a particular orientation for processing (e.g., by processing apparatus 180 thereof). Pass-through slots 116b may be able to receive one or more substrates 105 from a first substrate handling robot 150, which may then be retrieved by a second substrate handling robot 150. In contrast to pre-aligner element 116a, pass-through slots 116b may not serve to facilitate alignment of substrates 105 upon receipt. In some embodiments, pass-through slots 116b may be used when transferring substrates 105 from the processing tool 160 and/or buffer stations 190 to substrate carrier 140 (e.g., to a particular substrate storage module 142) for storage, as the orientation of the substrate 105 may not matter as much in such instances. The configuration of substrate exchange fixture 116 may vary depending on the embodiment and its application. In some embodiments, for example, substrate exchange fixture 116 may be provided with more than one pre-aligner element 116a (e.g., a pair of pre-aligner elements) that may be used to exchange multiple substrates 105.

FIG. 1C illustrates a perspective view of a substrate handling robot 150 that may be used in the integrated substrate processing system 100. As depicted in FIG. 1C, substrate handling robot 150 may include a base structure 151 that may be used to secure the substrate handling robot, for example, to a floor of EFEM 110 (e.g., to a support bracket 117 provided on a floor of a main compartment 112 thereof).

A support shaft 152 may be disposed within base structure 151 (e.g., within a cavity therein) and may be extendable through an opening provided in a top surface thereof. In some embodiments, for example, the substrate handling robot 150 may include a drive system that may be used to extend (or raise) and retract (or lower) the support shaft 152. In some embodiments, for instance, the drive system may include a linear actuator (e.g., a stepper or servomotor driven actuator) coupled to the support shaft 152 that may operate to extend (or raise) and retract (or lower) the support shaft 152 (e.g., along a vertical or Z axis). In some embodiments, for instance, the actuator may permit the support shaft 152 to be placed in a number of positions between a fully retracted (or fully lowered) position (e.g., in which support shaft 152 is recessed within base structure 151, for example, as illustrated in FIG. 1B) and a fully extended (or fully raised) position (e.g., in which support shaft 152 is maximally extended above base structure 151, for example, as illustrated in FIG. 1C).

Support shaft 152 may be used to support an articulating linkage 154, which may be movably coupled thereto. Raising and lowering of support shaft 152, thus, may also operate to raise and lower the articulating linkage 154 (e.g., in the Z direction). The articulating linkage 154 may have one or more end effectors 157 (e.g., a pair of end effectors 157a, 157b) provided at a terminal end (or terminal ends) thereof, which may interface with substrates 105. The form of end effectors 157 (e.g., shape, size, etc.) may vary depending on the embodiment and its application. In some embodiments, for example, the end effectors 157 may be shaped and sized so as to align with the shape and size of the substrates 105 that the end effectors 157 may handle. In some embodiments, for instance, end effectors 157 may be fork-shaped, e.g., having a pair of prongs, and have a width slightly smaller than that of the substrates 105 the end effectors 157 may handle. End effectors 157, thus, may provide a stable base on which the substrates 105 may be carried, while also allowing the substrates 105 to be gathered and deposited at different locations, with the outer portion of substrates 105 (i.e., beyond the outer width of end effectors 157) being able to interface with features at the location (e.g., with the fins of a substrate storage module 142 or buffer station 190, or raised lift pins 174 of stage 170).

The articulating linkage 154 may be manipulated to affect movement of the end effectors 157 between different positions (e.g., in a horizontal or X-Y plane). In some embodiments, for example, the articulating linkage 154 may comprise one or more arms 155 (e.g., arms 155a-d) that may be coupled together and movable relative to one another. In some embodiments, for instance, arms 155 may be coupled together end-to-end to form the articulating linkage 154. In some cases, multiple arms may be coupled to a common base arm to form separate branches of the articulating linkage 154. By way of example, as illustrated in FIG. 1, the articulating linkage 154 may include a first arm 155a that may be coupled to support shaft 152 at a first end thereof and to a second arm 155b at a second end thereof. The second arm 155b, in turn, may be coupled to the first arm 155a at a first end thereof and to a third and fourth arm 155c, 155d at a second end thereof (i.e., forming a pair of branches). The third and fourth arms 155c, 155d may be coupled to second arm 155b at a first end thereof and may have a pair of end effectors 157 coupled to (or formed as part of) second ends thereof (i.e., at terminal ends of articulating linkage 154).

The articulating linkage 154 may include one or more drive systems that may be used to manipulate the position of arms 155. In some embodiments, for example, the drive systems may provide for movement of some or all of arms 155 between a range of different positions with one or more degrees of freedom. The drive system, for instance, may provide for rotational movement (e.g., within a range of radial positions or with complete rotational freedom), linear movement (e.g., in a Z direction or a radially outward direction, etc.), or a combination thereof. In some embodiments, for instance, the drive systems may include one or more actuators or motors coupled to arms 155 that may operate to move arms 155 between different positions. In some embodiments, the actuators may be directly coupled to arms 155 of articulating linkage 154 (e.g., using direct drive motors), while in others, a transmission mechanism (e.g., a belt, chain, or gear assembly) may be used. In general, direct-drive systems may allow for more rapid and precise movement of the articulating linkage 154 (and end effectors 157) than transmission-based systems.

As an illustrative example, with reference to FIG. 1, a first motor may be provided (e.g., within support shaft 152) that may be used to rotate first arm 155a relative to support shaft 152 (e.g., about a central axis of support shaft 152 with 360° of rotational freedom); a second motor may be provided (e.g., within first arm 155a at a distal end thereof) that may be used to rotate second arm 155b relative to first arm 155a (e.g., with 360° of rotational freedom); and a third motor may be provided (e.g., within second arm 155b at a distal end thereof) that may be used to independently rotate third and fourth arms 155c, 155d relative to second arm 155b (e.g., each with 360° of rotational freedom). Through operation of each motor, the end effectors 157 of the articulating linkage 154 may be manipulated between a range of different positions in a horizontal plane. The articulating linkage 154, for example, may be placed in a collapsed position in which the arms 155 of articulating linkage 154 are folded atop one another (e.g., as illustrated in FIG. 1B), or in various extended positions (e.g., as illustrated in FIG. 1C).

Through manipulation of the articulating linkage 154 and adjustment of support shaft 152, end effectors 157 of substrate handling robots 150 may be used to transfer substrates 105—e.g., gather (or pick up), carry (or hold), and deposit (or set down) substrates 105—between different locations within the integrated processing environment 100a. Substrate handling robots 150, for example, may gather substrates 105 at a first location (e.g., from a substrate storage module 142, buffer station 190, or stage 170 of processing tool 160), for instance, by positioning the end effectors 157 below the substrates 105 and raising the end effectors 157 upward (e.g., by raising support shaft 152) to lift the substrates 105 (e.g., out of a slot of a substrate storage module 142 or buffer station 190, or off of raised lift pins 174 of stage 170). The substrate handling robots 150 may then move the end effectors 157 with substrates 105 thereon to a second location (e.g., to a substrate storage module 142, buffer station 190, or stage 170 of processing tool 160), where the end effectors 157 may be lowered to deposit the substrates 105 at the second location (e.g., into a slot of a substrate storage module 142 or buffer station 190, or onto raised lift pins 174 of stage 170).

The substrates 105 may be held in place (or secured) atop end effectors 157 during transit. In some embodiments, for example, substrates 105 may be secured (entirely or in part) by friction between the end effectors 157 (e.g., an upper surface of end effectors 157) and the substrates 105 (e.g., a lower surface of substrates 105). In some embodiments, end effectors 157 may be provided with a mechanism to assist with gathering, securing, and/or depositing substrates 105. In some embodiments, for example, end effectors 157 may be provided with a suction mechanism (e.g., a plunger or a vacuum source) that may operate to provide a pulling force to help gather and secure substrates 105 to end effectors 157, which may be released or stopped when depositing substrates 105.

In some embodiments, the substrate handling robots 105 may be able to perform relatively complex movements, which may not be possible or performed as efficiently (e.g., as quickly) with existing substrate handling robots in existing electronic device manufacturing systems using. A substrate transfer process, for example, may be performed as a series of discrete movements, each having an associated settling time that may pass before the next movement proceeds (e.g., before vibrations associated with the movement are sufficiently attenuated). The substrate handling robots 150 of the integrated substrate processing system 100 may be able to affect a substrate transfer process in fewer movements than existing systems (e.g., by eliminating and/or combining certain movements), reducing the overall transfer time (e.g., by reducing the total distance travelled and/or reducing the total amount of settling time). By way of example, a substrate transfer process may generally involve extending to a first location, gathering a substrate therefrom, moving to a second location, and depositing the substrate at the second location. In existing electronic device manufacturing systems, substrate handling robots will typically return to a home position after one or more of such movements, for example, returning to a home position after gathering a substrate from the first location before extending to a second location. The substrate handling robots 150 of the integrated substrate processing system 100 may be able to move directly between different locations without returning to a home position, for example, moving directly to a second location after gathering a substrate 105 at a first location. The total distance travelled by the substrate handling robot 150, thus, may be reduced (e.g., as a complete retraction and subsequent extension may be avoided) as well as the total amount of settling time (e.g., as only one movement, instead of two, is performed).

In some embodiments, the substrate handling robots 150 may be specially adapted to facilitate the rapid movement of substrates 105 (e.g., enabled by the use of direct-drive motors) between locations in the integrated processing environment 100a. For example, in some embodiments, the substrate handling robots 150 may rely on friction to hold substrates 105 in place atop end effectors 157 (as discussed above). In order to withstand forces that may be experienced during such rapid movements (e.g., up to 1 G of force when using direct-driven robots, as compared to a maximum of 0.3 G of force that may be sustained when using transmission-driven robots), the substrate handling robots may be provided with end effectors 157 having suitable frictional properties. In some embodiments, for example, end effectors 157 may be able to secure substrates 105 by friction alone. In some embodiments, for instance, end effectors 157 may be provided with frictional grips or pads that may secure substrates 105 by friction alone (e.g., to be able to withstand up to 1 G of force). In some applications, end effectors 157 (and/or the frictional grips or pads provided thereon) may also have certain electrostatic discharge (ESD) properties, so that the end effectors 157 may safely interface with substrates 105. In some embodiments, for instance, end effectors 157 may be provided with frictional grips or pads made of a perfluoroelastomeric compound (or FFKM) such as Perlast G90DM, a commercially available FFKM manufactured and sold by Precision Polymer Engineering, which may have frictional and ESD properties suitable for some applications.

FIG. 1D illustrates a side view of a processing tool enclosure 120 that may be used in the integrated substrate processing system 100. As previously discussed, the processing tool enclosure 120 may be coupled to EFEM 110 to form an integrated processing environment 100a, which the integrated substrate processing system 100 may operate to maintain at substantially uniform conditions throughout. The processing tool enclosure 120 may house a substrate processing tool 160 (e.g., a digital lithography tool) that may be used to process one or more substrates 105 (e.g., to perform a photolithography process thereon).

Substrates 105 may take a variety of forms (e.g., varying in material, size, shape, weight, etc.) depending on the embodiment and its application. In some embodiments, for example, a substrate 105 may be a wafer or panel made of quartz, silicon, or glass (e.g., borosilicate glass), plastic, or other suitable material for electronic device formation. In some embodiments, a substrate 105 may have a photoresist layer formed on its surface (e.g., a top and/or bottom surface), on which a pattern forming photolithography process may be performed. In some embodiments, a substrate 105 may have one or more areas (e.g., on a top and/or bottom surface) that are suitable for handling and/or contact (e.g., that are not being employed to create electrical features).

In some embodiments, a substrate 105 may be a rectangular substrate (e.g., a substrate panel, glass carrier panel, glass core panel, etc.) having a particular length and width (e.g., 510 mm×515 mm, 650 mm×550 mm, etc.), thickness (e.g., between 200 μm and 3.5 mm), and weight (e.g., between 100 g and 3.5 kg). In other embodiments, a substrate 105 may be a round or disk-shaped substrate (e.g., a silicon wafer, glass carrier wafer, etc.) having a particular diameter (e.g., 200 mm, 300 mm, etc.), thickness (e.g., between 500 μm and 2 mm), and weight. Substrates 105 may be generally flat in nature but may exhibit some amount of variation in flatness across their surface (e.g., variations in a Z direction relative to an X and/or Y dimension). Substrates 105, for example, may be warped to varying degrees (e.g., on account of prior processing and/or handling operations). A substrate 105, for instance, may exhibit some amount of concavity or convexity and/or have wave like variations across its surface. In some embodiments, an amount of variation in the flatness of a substrate 105 (e.g., an amount of warpage) may be specified in terms of a largest distance between a bottom side of substrate and a top surface of an object on which a substrate 105 may be disposed. Due to variations in flatness (e.g., due to warpage), the effective thickness of substrates 105 may vary (e.g., up to 2 mm). In some cases, the thickness of substrate 105 may be expressed in terms that account for or indicate the amount of variation (e.g., a thickness of 4 mm or 2 mm±2 mm).

The processing tool 160 may handle a number of different substrates 105 during operation. In some embodiments, for example, the processing tool 160 may handle substrates 105 having a same or similar shape and dimension (e.g., 300 mm round substrates). In some embodiments, substrates 105 may have a uniform or near uniform thickness, while in others, substrates 105 may have varying thicknesses.

Processing tool 160 may include a base frame 161 and a slab 162. The base frame 161 may rest on the floor of a fabrication facility and may support the slab 162, which may be a monolithic structure such as a large piece of granite or stone. The base frame 161 and slab 162 may provide a rigid and stable base on which a processing apparatus 180 and one or more movable stages (e.g., stage 170) may be disposed. In some embodiments, active and/or passive air isolators 163 may be positioned between the base frame 161 and slab 162 that may operate to provide vibration isolation and improve slab stability.

Stage 170 may be movably disposed on the slab 162 and adapted to receive one or more substrates 105 thereon (e.g., from substrate handling robots 150) and secure the substrates 105 thereto. In some embodiments, for example, processing tool 160 may include one or more drive systems that may provide for independent positioning and movement of stage 170 (e.g., in an X, Y, and/or Z direction relative to the slab 162). In some embodiments, the drive systems may provide for high-precision positioning and/or movement of stage 170 (e.g., at a micro or nano scale). In some embodiments, for instance, processing tool 160 may include one or more linear drive systems (e.g., an X and/or Y drive system) that can move stage 170 independently in different directions (e.g., in the X and/or Y directions). In some embodiments, for example, the linear drive systems may comprise one or more linear motors (e.g., cylindrical, U-channel, or flat type linear motors) to control movement of stage 170 (e.g., to a particular position at a particular velocity and/or rate of acceleration).

In some embodiments, for instance, processing tool 160 may include an X drive system comprising one or more forcers (e.g., having wire coils provided therein) that may move along one or more corresponding magnetic tracks, which may be disposed on a top surface of the slab 162 and oriented in the X direction. In some embodiments, for example, a pair of forcers may be coupled to opposite sides of a first support body (e.g., a carriage or slide) of stage 170 and may move along a pair of magnetic tracks to affect movement of the first support body in the X direction relative to a top surface 162a of the slab 162. Similarly, processing tool 160 may include a Y drive system comprising one or more forcers (e.g., having wire coils provided therein) that may move along on one or more corresponding magnetic tracks, which may be disposed on a top surface of the first support body and oriented in the Y direction. In some embodiments, for example, a forcer may be coupled to a second support body (e.g., a carriage or slide) of stage 170 and may move along a central magnetic track. Actuation of the X drive system, thus, may affect movement of the first support body and, by extension, the second support body in the X direction, and actuation of the Y drive system may affect movement of the second support body in the Y direction, providing for movement of stage 170 relative to a top surface 162a of slab 162. In some embodiments, processing tool 160 may include one or more bearings (not shown in FIG. 1) to facilitate movement of stage 170. In some embodiments, for instance, processing tool 160 may include air bearings disposed between the first support body and a top surface 162a of the slab 162 and air bearings disposed between the second support body and a top surface 162a of the slab 162 that may provide pressurized air to levitate stage 170 during movement.

In some embodiments, processing tool 160 may be provided with one or more encoders, sensors, and/or accelerometers that may be used to provide positional, velocity, and/or acceleration information (e.g., to a processing tool controller (not shown in FIG. 1). In some embodiments, for example, an encoder (e.g., an optical encoder, rotary encoder, etc.) may be coupled to stage 170 or a linear drive system thereof that may be used to determine a position, velocity, and/or acceleration of the stage 170, and any substrates 105 thereon, which may be provided to a processing tool controller. In some cases, an actual position of stage 170 and the position measured by an encoder may differ, and in some embodiments, a more accurate position measurement may be provided by one or more additional sensors. In some embodiments, for example, a plurality of interferometers (not shown in FIG. 1) may be used to measure the position of stage 170 and any substrates 105 thereon, which may be provided to the processing tool controller. A number of different types of interferometers may be used depending on the embodiment and its application, including for example, high stability plane mirror (HSPM) interferometers may be used.

As noted above, stage 170 may be adapted to receive and secure one or more substrates for processing. By way of example, stage 170 may be able to receive and secure four substrates (e.g., as shown in FIG. 1E), though fewer or greater numbers of substrates 105 may be received and secured in other embodiments (e.g., two, six, etc.). The number of substrates 105 accommodated by stage 170 may impact the processing throughput of the integrated substrate processing system 100. In general, for example, increasing the number of substrates 105 accommodated by stage 170 may increase the processing throughput of the integrated substrate processing system 100.

In some embodiments, stage 170 may include a chuck 172 on which one or more substrates 105 may be received (or from which substrates 105 may be gathered). Chuck 172 may be coupled atop (or integrally formed as part of) a support body of stage 170 (e.g., atop a second support body thereof). The form of chuck 172 (e.g., material size, shape, etc.) may vary depending on the embodiment and its application (e.g., depending on the number, shape, and size of substrates that may be received). For example, as illustrated in FIG. 1E, chuck 172 may be able to receive and secure four round substrates 105 (e.g., 300 mm round substrates) in four regions thereof. In some embodiments, chuck 172 may be made of the same material as the second support body, such as aluminum. In some embodiments, chuck 172 may be made of (or coated with) a different material, such as silicon or a ceramic material, which may help to reduce backside contamination of a substrate 105. In some embodiments, chuck 172 may be rectangular in form, while in others, chuck 172 may be round or disk-shaped. In some embodiments, chuck 172 may have a surface area of approximately 1 square meter, though larger or smaller chucks may be suitable for other embodiments and applications.

In some embodiments, stage 170 may include a plurality of lift pins 174 that may be used to receive substrates 105 on chuck 172 (or present substrates 105 to be gathered from chuck 172). In embodiments where chuck 172 accommodates multiple substrates 105, different subsets of lift pins 174 may be used to receive (and present) substrates 105 (e.g., in different regions of chuck 172). For example, with reference to FIG. 1E, four subsets of lift pins 174 (e.g., subsets of three lift pins 174) may be used, in each of four different regions of chuck 172, to receive (and present) a substrate 105 (e.g., a round substrate 105). In some embodiments, for example, chuck 172 may have a plurality of clearance holes formed therethrough, which may be sized and shaped so as to accommodate lift pins 174 therein. In some embodiments, lift pins 174 may be coupled to (or integrally formed as part of) one or more lift pin structures disposed within stage 170 (e.g., within a second support body thereof), which may be coupled to one or more lift pin actuators that may operate to move the lift pin structures (and lift pins 174) in the Z direction (i.e., through corresponding clearance holes). The lift pin actuators, for example, may operate to move the lift pin structures from an initial position, where respective lift pins 174 are fully recessed below a top surface of chuck 172 (e.g., within a second support body of stage 170), to a final position, where lift pins 174 are fully extended (i.e., through the clearance holes and beyond a top surface of chuck 172).

In embodiments where stage 170 accommodates multiple substrates 105, lift pins 174 may operate together, for example, to raise and lower substrates 105 simultaneously. In other embodiments, lift pins 174 (or subsets thereof) may be able to operate to raise and lower each substrate 105 independently. In some embodiments, for example, each substrate 105 may be raised and lowered by a subset of lift pins 174, which may be coupled to separate lift pin structures having separate actuators that may be raised and lowered independently. For example, with reference to FIG. 1E, different subsets of lift pins 174, in each of four different regions of chuck 172, may operate independently to raise and lower substrates 105 thereon.

Lift pins 174 may be appropriately positioned and of sufficient length to facilitate substrate transfer by a substrate handling robot 150. Lift pins 174, for example, may be positioned so as to provide adequate space between lift pins 174 through which the end effectors 157 of the substrate handling robot 150 may enter and exit. Lift pins 174 may also be of sufficient length to provide adequate space between a top surface of chuck 172 and a surface formed by lift pins 174 when fully extended (e.g., on which a substrate 105 may rest) for end effectors 157 to enter (e.g., with substrates 105 in place atop lift pins 174) and exit (e.g., into which end effectors 157 may descend to drop substrates 105 off onto lift pins 174). Lift pins 174 may also be relatively oriented so as to facilitate the entry of end effectors 157 there between. By way of example, with reference to FIG. 1E, subsets of lift pins 174, in each of four different regions of chuck 172, may be used to receive a substrate 105 thereon. Each subset of lift pins 174 may be arranged in an annular fashion so as to align with an outer perimeter of a substrate 105 (e.g., a round substrate 105) that may be brought to rest thereon. The lift pins 174 may be spaced apart and radially oriented so as to permit entry of an end effector 157 therebetween.

In some embodiments, stage 170 may include a mechanism to secure substrates 105 thereto (e.g., to chuck 172). In some embodiments, for example, stage 170 may include a chucking mechanism (e.g., a vacuum chucking mechanism, an electrostatic chucking mechanism, or the like) that may operate to apply a downward pulling force on substrates 105 and secure them to chuck 172. In some embodiments, for example, a vacuum chucking mechanism may include a vacuum source (not shown in FIG. 1) that may be in fluid communication with one or more ports or apertures formed in chuck 172. The vacuum source may operate to pull air through the apertures, which may apply a downward pulling force on a substrate 105 pulling the substrate 105 toward chuck 172 and securing the substrate 105 thereto. In some embodiments, the vacuum chucking mechanism may provide for different chucking zones. The vacuum source, for example, may be able to pull air through apertures independently and may operate to pull air through a subset of one or more apertures to provide different chucking zones (e.g., corresponding to different substrates 105).

As noted above, processing tool 160 may also include a processing apparatus 180 that may be used to process substrates 105. In some embodiments, for example, processing apparatus 180 may comprise a support 181 (e.g., disposed on slab 162) and one or more processing units 184 secured thereto for processing substrates 105. In some embodiments, for instance, support 181 may be a gantry structure having one or more bridges (e.g., bridges 181a) that span slab 162 (e.g., in the Y direction) and provide an opening 182 thereunder. Processing units 184 may be secured to bridges 181a and disposed above opening 182, which may be suitably sized to permit stage 170 to pass under processing units 184 and allow the processing units 184 to operate on substrates 105 provided thereon.

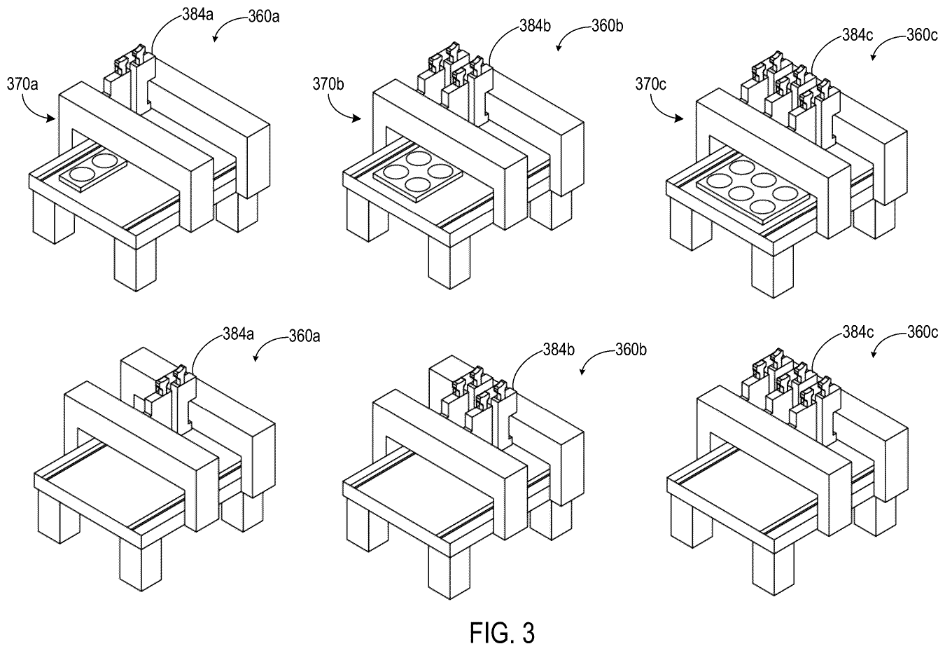

In some embodiments, the number of processing units 184 in the processing apparatus 180 may correspond to the number of substrates 105 accommodated by stage 170. The processing apparatus 180 of FIG. 1, for example, may include four processing units 184, which may allow the processing apparatus 180 to simultaneously process four substrates 105 that may be accommodated on stage 170 (e.g., received and secured to chuck 172 thereof). Depending on the embodiment and its application the number of substrates accommodated by stage 170 (e.g., received and secured to chuck 172 thereof) and a corresponding number of processing units 184 may vary. The number of substrates accommodated by stage 170 and corresponding number of processing units 184, for example, may be chosen to achieve a target substrate processing throughput. By way of example, with reference to FIG. 3, different processing tools 360 are shown (e.g., with respective stages 370 in a load/unload position and a processing position under processing apparatus 380) that are capable of simultaneously processing different numbers of substrates. As illustrated in FIG. 3, processing tool 360a may be able to accommodate two substrates on stage 370a that may be simultaneously processed by a processing apparatus 380a having two processing units 384a; processing tool 360b may be able to accommodate four substrates on stage 370b that may be simultaneously processed by a processing apparatus 380b having four processing units 384b; and processing tool 360c may be able to accommodate six substrates on stage 370c that may be simultaneously processed by a processing apparatus 380c having six processing units 384c. The integrated substrate processing system 100 may further vary based on the number of substrates accommodated by stage 170, for example, including fewer or additional substrate processing robots 150, having fewer or greater number of end effectors 157, including fewer or additional buffer stations 190, and/or in some other respect.

Returning to FIG. 1C, in some embodiments, processing units 184 may be pattern generators configured to expose a photoresist disposed on a substrate 105 to a photolithography process. Processing units 184, for instance, may be pattern generators configured to perform a maskless lithography process. In some embodiments, processing units 184 may include one or more image projection systems disposed in a housing that may direct one or more light sources onto specific areas of a photoresist (e.g., as a substrate 105 passes under the processing unit 184). The image projection systems, for example, may be part of a digital light projector device that utilizes laser light. In some embodiments, multiple laser light sources may be combined and projected onto a digital micro-mirror (e.g., a multi-faceted mirror) that redirects the light onto specific areas of the photoresist.

During operation, stage 170 may be placed in a home position (or a load/unload position), where stage 170 may be clear of the processing apparatus 180 and accessible by substrate handling robots 150 (e.g., by one or more end effectors 157 thereof). Lift pins 174 may then be moved from an initial fully recessed position to a to a final fully extended position, after which substrate handling robots 150 may load one or more (unprocessed) substrates 105 (e.g., from substrates storage modules 142 or buffer stations 190) onto the raised lift pins 174. The lift pins 174 may be gently lowered back to an initial fully recessed position, placing substrates 105 onto stage 170 (e.g., onto chuck 172).

The substrates 105 may then be secured to stage 170 (e.g., to chuck 172 using a chucking mechanism), after which stage 170 and substrates 105 may be moved to an initial processing position under processing apparatus 180. Substrates 105 may then undergo processing (e.g., undergo a photolithography process) by processing apparatus 180 and processing units 184 thereof. During processing, stage 170, and substrates 105 may be moved between different processing positions under processing apparatus 180, for example, to adjust the position of substrates 105 relative to processing units 184.

Once processing is complete, stage 170 may return to a home position (or a load/unload position), after which lift pins 174 may again be moved from a fully recessed position to a fully extended position, lifting the (processed) substrates 105 off of stage 170. The substrate handling robots 150 may unload and store the (processed) substrates 105 (e.g., in substrates storage modules 142), and a next processing iteration may begin, for example, with the substrate handling robots 150 placing one or more additional (unprocessed) substrates 105 onto lift pins 174.

As previously noted, in some embodiments, the processing tool enclosure 120 may be provided with one or more buffer stations 190 (not shown in FIG. 1D) that may help facilitate the efficient sequential processing of substrates 105 (e.g., over multiple processing iterations or cycles). The buffer stations 190 may be positioned near the processing tool 160 and used to intermediately stage substrates 105 so that the amount of time spent between processing iterations (e.g., to unload and load substrates 105 from the processing tool 160) may be minimized. Transferring substrates 105 between the substrate carrier 140 and the processing tool 160 before and after each processing iteration, for example, may take a relatively long period of time, as doing so may involve traversing a relatively long distance and performing a relatively complex series of movements (e.g., by substrate handling robot 150). Instead, substrates 105 can be quickly swapped between the buffer stations 190 and processing tool 160 between processing iterations (e.g., on account of a shorter and more direct path between the buffer station 190 and processing tool 160) and transferred between the buffer stations and the substrate carrier during a previous or subsequent processing iteration (e.g., during which the substrate handling robots may otherwise be idle).

FIG. 1E illustrates a top cross-sectional view of a portion of the integrated substrate processing system 100 (e.g., taken along C-C of FIG. 1A), which depicts the substrate carrier 140 (e.g., above storage substrate modules 142), the EFEM 110 (e.g., within main compartment 112 below ionization device 136), and an adjacent portion of processing tool enclosure 120 (e.g., below a top wall thereof). The integrated substrate processing system 100 is shown in a state of operation, with the stage 170 of processing tool 160 in a home position (or load/unload position) and end effectors 157a-157d of substrate handling robots 150a, 150b positioned above the processing stage 170 with substrates 105 provided thereon. The substrate handling robots 150, for example, may be in the process of loading or unloading substrates 105 from the processing stage 170. The substrate handling robots 150, for instance, may be used to transfer substrates 105 between substrate carrier 140 (e.g., from/to slots in substrate storage modules 142 thereof), processing tool 160 (e.g., to/from stage 170 thereof), and/or buffer stations 190 (e.g., to/from slots therein). Further detail regarding the structure and function of the substrate carrier 140 and substrate storage modules 142 as well as buffer stations 190 is provided below.

As previously discussed, the EFEM 110 may be coupled to (or formed with) a substrate carrier 140 that may be used to store one or more substrates 105, for example, before and/or after being processed by processing tool 160. The substrate carrier 140, for example, may include one or more storage modules 142 (e.g., as illustrated in FIG. 1E, substrate storage modules 142a-142d), which may be able to safely store a number of individual substrates 105 (e.g., up to 25 substrates). Each substrate storage module 142, for example, may include a number of slots in which a substrate 105 may be stored. In some embodiments, for example, the substrate storage module 142 may include a number of fins on which a substrate 105 may rest (e.g., upon pads provided on a surface thereof). In some embodiments, the fins may be stacked together (e.g., vertically stacked), with a gap (or space) provided between adjacent fins, to form a series of slots in which a substrate 105 may be stored. In some embodiments, the fins may be coupled together (e.g., attached to a spine or the like) to form a unitary structure.

The configuration of substrate storage modules 142 may vary depending on the embodiment and its application, for example, accommodating different numbers of substrates 105 (e.g., having 10 slots, 25 slots, etc.) and/or substrates 105 of different shape, size, and/or thickness. The slot pitch (e.g., space between fins) of a substrate storage module 142, for example, may vary depending on the embodiment (e.g., depending on the maximum thickness of the substrates 105 expected to be stored). By way of example, in some embodiments, substrate storage modules 142 may have a slot pitch of between 5-6 mm, which may be used to store substrates 105 having a thickness of 2 mm±2 mm (e.g., to account for variations due to warpage).

The substrate storage modules 142 may be designed to allow substrate handling robots 150 (e.g., in EFEM 110) to transfer substrates 105 therefrom and thereto. A substrate handling robot 150, for example, may be able access each slot of the substrate storage module 142 (e.g., through one or more openings 141 in EFEM 110) to select or deposit substrates 105 therefrom or thereto. In some embodiments, for example, the fins of the substrate storage module may be shaped so as to provide a central channel through which an end effector 157 of a substrate handling robot 150 may be able to pass. An end effector 157 of the substrate handling robot 150 (e.g., provided at a terminal end of an articulating linkage 154 thereof), thus, may be able to gather substrates 105 off of, or deposit substrates 105 onto, the fins of the substrate storage module 142. In some cases, a substrate handling robot 150 may be used to transfer multiple substrates 105 to or from a substrate storage module 142.

As an illustrative example, with reference to FIG. 1E, substrate handling robot 150a may be used to gather a pair of substrates 105 from substrate storage module 142a, which may be stored in adjacent slots therein. Substrate handling robot 150a, for instance, may position end effectors 157a, 157b below an initial target slot of the substrate storage module 142a and in alignment with a central channel thereof (e.g., with end effector 157a overlapping end effector 157b). The end effectors 157a, 157b, for example, may be positioned within one or more slots below the target slot or below the substrate module 142a altogether (e.g., where the initial target slot is a bottom-most slot of the substrate storage module 142a). The substrate handling robot 150a may then raise end effector 157a to gather a first substrate 105 from the target slot (e.g., through adjustment of support shaft 152). The end effector 157a, for example, may enter into the target slot and lift the substrate 105 off of a fin thereof, whereafter the end effector 157a and substrate 105 may remain within the target slot. Raising end effector 157a may also result in raising end effector 157b (e.g., due to their common coupling to articulating linkage 514 and support shaft 152). The substrate handling robot 150a may remove the end effector 157a from the substrate storage module 142 while keeping end effector 157b in place (e.g., by rotating arm 155c and swinging the end effector 157a and substrate 105 thereon clear of the substrate storage module 142). The substrate handling robot 150a may then proceed to raise the end effector 157b to gather a second substrate 105 from a next slot (e.g., above the initial target slot). The end effector 157b, for example, may enter into the next slot and lift the substrate 105 off of a fin thereof, whereafter the end effector 157b and substrate 105 may remain within the next slot. The substrate handling robot 150 may remove end effector 157b from the substrate storage module 142a (e.g., by retracting the articulating linkage 154 or rotating arm 155d and swinging the end effector 157b free of the substrate storage module 142) and start moving toward a target destination.

Substrate handling robot 150a, for example, may move end effectors 157a, 157b and substrates 105 thereon into the processing tool enclosure 120, where the substrates 105 may be deposited onto a processing tool 160 (e.g., on a stage 170 thereof). Substrate handling robot 150a, for instance, may move end effectors 157a, 157b and the substrates 105 thereon, through opening 104 in EFEM 110, into position over stage 170 (e.g., over two separate regions of a chuck 172 thereof, as shown in FIG. 1E). The end effectors 157a, 157b, for example, may be moved into position over corresponding sets of lift pins 174, which may be in a fully extended position above a surface of chuck 172 of stage 170. The substrate handling robot 150a may then lower end effectors 157a, 157b (e.g., in some cases, in a single movement) to deposit substrates 105 onto the extended lift pins 174. The end effectors 157a, 157b, for example, may enter between the extended lift pins 174 and place the substrates 105 on the extended lift pins 174, whereafter the end effectors 157a, 157b may be positioned in the space provided between the extended lift pins 174 and chuck 172. The substrate handling robot 150a may withdraw end effectors 157a, 157b therefrom (e.g., by retracting articulating linkage 154 and end effectors 157a, 157b through the space provided between extended lift pins 174), at which point the substrate handling robot 150 may be ready to begin another substrate transfer process.

A substrate handling robot 150 may follow a similar process to gather substrates 105 from processing tool 160 (e.g., from a stage 170 thereof) and deposit them in a substrate storage module 142. Substrate handling robot 150a, for example, may position end effectors 157a, 157b below a pair of substrates 105, which may be raised above chuck 172 of stage 170 on corresponding sets of lift pins 174 (e.g., in two separate regions thereof). The end effectors 157a, 157b, for example, may enter between extended lift pins 174 into the space provided between chuck 172 and substrates 105 resting thereupon. The substrate handling robot 150a may then raise end effectors 157a, 157b (e.g., in some cases, in a single movement) to gather substrates 105 from the extended lift pins 174. The substrate handling robot 150a, for example, may raise end effectors 157a, 157b until the end effectors 157a, 157b are clear of the extended lift pins 174, lifting substrates 105 off the lift pins 174 in the process, whereafter the substrates 105 may be held by end effectors 157a, 157b above the stage 170 of processing tool 160.

The substrate handling robot 150a may then move end effectors 157a, 157b (and substrates 105 resting thereon) toward substrate storage module 142a to be deposited in adjacent slots therein. Substrate handling robot 150a, for instance, may position end effector 157b adjacent to the substrate storage module 142a in line with an initial target slot. The substrate handling robot 150a may then move end effector 157b (and substrate 105 thereon) into the target slot (e.g., by rotating arm 155d and swinging end effector 157b into the target slot) and in alignment with a central channel thereof. The substrate handling robot 150a may then lower end effector 157b to deposit a first substrate 105 in the target slot. The end effector 157b, for example, may be lowered past the target slot (e.g., entering into a lower slot there below), placing the substrate 105 onto a fin thereof. Lowering of end effector 157b may also operate to bring end effector 157a in line with a next slot (e.g., below the initial target slot), allowing the substrate handling robot 150a to move end effector 157a into the next slot (e.g., by rotating arm 155c and swinging end effector 157a into the target slot) and in alignment with a central channel thereof. The substrate handling robot 150a may lower end effector 157a to deposit a second substrate 105 into the next slot, whereafter the end effectors 157a and 157b may be removed from the substrate storage module 142a (e.g., by retracting the articulating linkage 154, rotating arms 155c, 155d and swinging the end effector 157a, 157b free of the substrate storage module 142, or lowering end effectors 157a, 157b through the central channel to below the substrate storage module 142a), at which point the substrate handling robot 150 may be to begin another substrate transfer process.

It will be appreciate that the above-described transfer of substrates 105 by substrate transfer robot 150a between substrate storage module 142a and stage 170 of processing tool 160 is merely illustrative, and may be extended to the transfer of additional or fewer substrates 105, by the same or different substrate handling robots 150 (e.g., substrate handling robots 150b), between the same or different substrate storage modules 142 (e.g., substrate storage modules 142b-142d), and/or between the same or different regions of the stage 170 of processing tool 160 (e.g., as illustrated in FIG. 1E with respect to substrate handling robot 150b). The transfer of substrates 105 may additionally involve the exchange of substrates 105 between substrate handling robots 150, for example, using a substrate exchange fixture 116 within the EFEM 110 (e.g., as described above with reference to FIG. 1B). In some cases, accessing a particular slot of the substrate storage module 142 may not always be practically feasible for a substrate handling robot 150, for example, where an end effector 157 cannot be positioned below a target slot or pass into a lower slot (e.g., on account of the slot pitch, the thickness of the end effector 157 itself, the presence of a substrate 105 thereon, and/or the presence of a substrate 105 in a slot there below). Therefore, in some cases, the substrate handling robots 150 may operate to retrieve substrates 105 sequentially from substrate storage modules 142 (e.g., from bottom to top) and deposit substrates 105 sequentially thereto (e.g., from top to bottom).

As previously discussed, in some embodiments, the processing tool enclosure 120 may be provided with one or more buffer stations 190 (e.g., as illustrated in FIG. 1E, four buffer stations 190a-190d) that may help facilitate the efficient sequential processing of substrates 105 (e.g., over multiple processing iterations or cycles). The buffer stations 190, for example, may be positioned near a processing tool 160 (also provided within the processing tool enclosure 120) and used to intermediately stage substrates 105. That is, instead of transferring substrates between substrate carrier 140 (e.g., to or from substrate storage modules 142 therein) and processing tool 160 (e.g., before and after each processing iteration), substrates 105 may be quickly swapped between the buffer stations 190 and processing tool 160 between processing iterations and transferred between the buffer stations 190 and the substrate carrier 140 during a previous or subsequent processing iteration. The amount of time spent between processing iterations (e.g., to unload and load substrates 105 from the processing tool 160), thus, may be minimized (e.g., on account of a shorter and more direct path between the buffer stations 190 and processing tool 160 than with substrate carrier 140).

In some embodiments, for example, the buffer stations 190 may include a number of slots that may be used to store a number of individual substrates 105 (e.g., up to 9 substrates). In some embodiments, for example, the buffer stations 190 may include a number of shelves on which a substrate 105 may rest (e.g., upon pads provided on a surface thereof). In some embodiments, the shelves may be stacked together (e.g., vertically stacked), with a gap (or space) provided between adjacent shelves, to form a series of slots in which a substrate 105 may be stored. In some embodiments, the shelves may be coupled together (e.g., attached to a spine or the like) to form a unitary structure. In some embodiments, multiple buffer stations 190 may be coupled together to form (or integrally formed as) a combined structure, for example, to ensure that their relative position (e.g., relative spacing and orientation) may be precisely controlled. By way of example, while buffer stations 190a, 190b and buffer stations 190c, 190d are illustrated as separate structures in FIG. 1, the buffer stations may be respectively formed as a combined structure (e.g., in which the buffer stations are relatively positioned as illustrated in FIG. 1E).

The number of buffer stations 190 and their respective configurations may vary depending on the embodiment and its application. For example, while FIG. 1E is illustrated as including four buffer stations 190a-190d, a fewer or greater number of buffer stations 190 (e.g., 2 buffer stations, 6 buffer stations, etc.) may be provided (e.g., depending on the number of substrate handling robots 150 and/or the number of substrates 105 that may be accommodated on stage 170 of processing tool 160). The number of substrates 105 accommodated by buffer stations 190 may also vary, for example, with buffer stations 190 providing different number of slots (e.g., 5 slots, 9 slots, 13 slots, etc.). In some embodiments, the number of buffer stations 190 and/or number of substrates 105 accommodated by the buffer stations 190 (e.g., collectively, in slots therein) may be chosen based on the number of substrates 105 that may be stored in a substrate storage module 142. The buffer stations 190, for example, may provide enough slots for all of the substrates 105 in a particular substrate storage module 142 to be staged within the buffer stations 190, for example, to allow for the processing of substrates 105 sequentially (e.g., retrieved from bottom to top and deposited from top to bottom). The configuration of buffer stations 190 may also vary to accommodate substrates 105 of different shape, size, and/or thickness. The slot pitch (e.g., space between shelves) of a buffer station 190, for example, may vary depending on the embodiment (e.g., depending on the maximum thickness of the substrates 105 expected to be stored) and its application (e.g., depending on the manner in which substrates 105 may be transferred therefrom and thereto). In some embodiments, for example, buffer stations 190 may be used to store substrates 105 having a thickness of 2 mm±2 mm (e.g., to account for variations due to warpage), but may have a relatively larger slot pitch, for example, of between 32-33 mm, which may help facilitate the efficient transfer of substrates 105 therefrom and thereto (e.g., facilitating the simultaneous transfer of substrates 105 as discussed in further detail below).

The buffer stations 190, for example, may be designed to allow substrate handling robots 150 (e.g., in EFEM 110) to transfer substrates 105 therefrom and thereto. A substrate handling robot 150, for instance, may be able access each slot of the buffer station 190 (e.g., through one or more openings 104 in EFEM 110) to gather or deposit substrates 105 therefrom or thereto. In some embodiments, for example, the shelves of the buffer station may be shaped (e.g., generally U-shaped or C-shaped) so as to provide a central channel through which an end effector 157 of a substrate handling robot 150 may be able to pass. An end effector 157 of the substrate handling robot 150 (e.g., provided at a terminal end of an articulating linkage 154 thereof), thus, may be able to gather substrates 105 off of, or deposit substrates 105 onto, the shelves of the substrate storage module 142.

In some embodiments, buffer stations 190 may be designed to facilitate the simultaneous transfer of multiple substrates 105 therefrom and thereto (e.g., between buffer stations 190 and stage 170 of processing tool 160). In some embodiments, for example, one or more substrate handling robots 150 may be used to simultaneously transfer one or more substrates 105 to or from buffer stations 190. By way of example, with reference to FIG. 1E, substrate handling robots 150a, 150b may each be able to simultaneously transfer a pair of substrates 105 between stage 170 of processing tool 160 and buffer stations 190a, 190b and buffer stations 190c, 190d (e.g., to or from parallel slots thereof), respectively, collectively operating to transfer four substrates 105 simultaneously. Substrates 105, thus, may be more efficiently transferred (e.g., as compared to transferring a single substrate 105 at a time) between the buffer stations 190 and processing tool 160, which may help to minimize the amount of time spent between processing iterations (e.g., to unload and load substrates 105 from the processing tool 160).

As an illustrative example, with reference to FIG. 1E, substrate handling robots 150 may be used to gather four unprocessed substrates from buffer stations 190 and deposit them on stage 170 of processing tool 160. Substrate handling robots 150a, 150b, for instance, may use end effectors 157a, 157b and end effectors 157c, 157d to gather unprocessed substrates 105 from parallel slots of buffer stations 190a, 190b and buffer stations 190c, 190d, respectively. By way of example, substrate handling robot 150a may position end effectors 157a, 157b below parallel target slots of buffer stations 190a, 190b and in alignment with central channels thereof. The end effectors 157a, 157b, for example, may be positioned within an adjacent slot below the target slot (or below the buffer stations 190a, 190b altogether). The slot pitch, for example, may be sufficiently large so as to accommodate end effectors 157a, 157b within the lower slot (e.g., accounting for the thickness of the end effectors 157a, 157b and the presence of substrates 105 in the lower slots). The substrate handling robot 150a may then raise end effectors 157a, 157b (e.g., in some cases, in a single movement) to gather substrates 105 from each target slot. The end effectors 157a, 157b, for example, may enter into the target slot and lift the substrates 105 off of shelves thereof, whereafter the end effectors 157a, 157b and substrates 105 thereon may remain within the target slot. Substrate handling robot 150b may simultaneously perform a similar process to gather unprocessed substrates 105 from parallel slots of buffer stations 190c, 190d.

The substrate handling robots 150a, 150b may then move end effectors 157a, 157b and end effectors 157c, 157d (and substrates 105 thereon) into position over respective regions of stage 170 of processing tool 160. The substrate handling robots 150a, 150b, for example, may move end effectors 157a, 157b and end effectors 157c, 157d into position over separate regions of stage 170 (e.g., over corresponding sets of lift pins 174, which may be in a fully extended position above a surface of chuck 172 of stage 170), as shown in FIG. 1E. In some embodiments, the buffer stations 190a-190d may be configured to simplify the movement of substrate handling robots 150a, 150b. For instance, while in some cases, substrate handling robots 150a, 150b may be able to manipulate articulating linkage 154 and adjust support shaft 152 at the same time, in others, manipulating articulating linkage 154 and adjusting support shaft 152 may be treated as discrete movements (e.g., each carrying a separate settling time). Furthermore, in some cases, adjustment of support shaft 152 may be relatively slow, for example, as compared to manipulation of articulating linkage 154. Accordingly, in some embodiments, the buffer stations 190a-190d may be configured to simplify the movements of substrate handling robots 150a, 150b when transferring substrates therefrom and thereto by minimizing (or eliminating) the amount of (or need for) adjustment of support shaft 152. In some embodiments, for example, buffer stations 190a-190d may be positioned at generally the same height as the processing stage 170 such that the target slots may be at a slightly higher level than the stage 170 (and extended lift pins 174). End effectors 157a, 157b and end effectors 157c, 157d may be swung into place above stage 170 (e.g., over corresponding sets of lift pins 174) through manipulation of articulating linkage 154 alone (e.g., without adjustment of support shaft 152). In some embodiments, buffer stations 190a, 190b and buffer stations 190c, 190d may also be oriented relative to one another in a similar manner as the different sets of lift pins 174 (e.g., in different regions of chuck 172) on which the substrates 105 may be placed. Substrate handling robots 150a, 150b may be able to move end effectors 157a, 157b and end effectors 157c, 157d into place in a relatively smooth motion (e.g., with the position of arms 155c, 155d remaining fixed, relative to one another, throughout).

Once in position above stage 170, end effectors 157a, 157b and end effectors 157c, 157d may be lowered (e.g., in some cases, in a single movement) to deposit substrates onto the extended lift pins 174 (e.g., entering between the extended lift pins 174 and depositing substrates 105 thereon, whereafter the end effectors may be positioned between the extended lift pins 174 and chuck 172). Substrate handling robots 150a, 150b may then withdraw end effectors 157a, 157b and end effectors 157c, 157d (e.g., by retracting articulating linkage 154 and end effectors 157a, 157b and effectors 157c, 157d through the space provided between extended lift pins 174), at which point substrate handling robots 150a, 150b may be ready to begin another substrate transfer process.

The substrate handling robots 150a, 150b may follow a similar process to gather four processed substrates 105 from processing tool 160 (e.g., from stage 170 thereof) and deposit them into buffer stations 190. Substrate handling robots 150a, 150b, for instance, may use end effectors 157a, 157b and end effectors 157c, 157d to gather a pair of processed substrates 105 from the processing tool 160. The substrate handling robots 150a, 150b, for example, may position end effectors 157a, 157b and end effectors 157c, 157d below the substrates 105, which may be raised above chuck 172 of stage 170 on corresponding set of lift pins 174 (e.g., in four separate regions thereof). The end effectors 157a, 157b and end effectors 157c, 157d, for example, may enter between extended lift pins 174 into the space provided between chuck 172 and substrates 105 resting thereupon. The substrate handling robots 150a, 150b may then raise end effectors 157a, 157b and end effectors 157c, 157d (e.g., in some cases, in a single movement) to gather substrates 105 from the extended lift pins 174. The substrate handling robots 150a, 150b, for example, may raise end effectors 157a, 157b and end effectors 157c, 157d until the end effectors are clear of the extended lift pins 174, lifting substrates 105 off the lift pins 174 in the process, whereafter the substrates 105 may be held by end effectors 157a, 157b and end effectors 157c, 157d above the stage 170 of processing tool 160 (e.g., as illustrated in FIG. 1E).

The substrate handling robots 150a, 150b may then move end effectors 157a, 157b and end effectors 157c, 157d and substrates 105 resting thereon into position to deposit the substrates in parallel slots of buffer stations 190a, 190b and buffer stations 190c, 190d, respectively. By way of example, substrate handling robot 150a may move end effectors 157a, 157b into position within a target slot and in alignment with a central channel thereof. The slot pitch, for example, may be sufficiently large so as to accommodate end effectors 157a-157d within the target slots above shelves thereof (e.g., accounting for the thickness of the end effectors 157a-157d and the presence of substrates 105 thereon). In some embodiments, buffer stations 190a, 190b may be configured to simplify the movement of substrate handling robot 150a. For instance, while in some cases, substrate handling robot 150a may be able to manipulate articulating linkage 154 and adjust support shaft 152 at the same time, in others, manipulating articulating linkage 154 and adjusting support shaft 152 may be treated as discrete movements (e.g., each carrying a separate settling time). Furthermore, in some cases, adjustment of support shaft 152 may be relatively slow, for example, as compared to manipulation of articulating linkage 154. Accordingly, in some embodiments, buffer stations 190a, 190b may be configured to simplify the movements of substrate handling robots 150a when transferring substrates therefrom and thereto by minimizing (or eliminating) the amount of (or need for) adjustment of support shaft 152. In some embodiments, for example, buffer stations 190a, 190b may be positioned at generally the same height as the processing stage 170 such that the target slots may be at a higher level than the stage 170 (and extended lift pins 174). End effectors 157a, 157b may be swung into place within the target slots through manipulation of articulating linkage 154 alone (e.g., without adjustment of support shaft 152). In some embodiments, buffer stations 190a, 190b may also be oriented relative to one another in a similar manner as the different sets of lift pins 174 (e.g., in different regions of chuck 172) from which the substrates 105 were retrieved. Substrate handling robots 150a may be able to move end effectors 157a, 157b into place in a relatively smooth motion (e.g., with the position of arms 155c, 155d remaining fixed, relative to one another, throughout).

Once in position within the target slots, substrate handling robot 150a may lower end effectors 157a, 157b (e.g., in some cases, in a single movement) to deposit substrates 105 into each target slot. The end effectors 157a, 157b, for example, may enter into adjacent slots below the target slots, placing the substrates 105 on shelves of the target slot, whereafter the end effectors 157a, 157b may remain within the lower slot. The slot pitch, for example, may be sufficiently large so as to accommodate end effectors 157a, 157b within the lower slot (e.g., accounting for the thickness of the end effectors 157a, 157b and the presence of substrates 105 in the lower slots). Substrate handling robot 150b may simultaneously perform a similar process to deposit processed substrates 105 into parallel slots of buffer stations 190c, 190d. The substrate handling robots 150a, 150b may then remove end effectors 157a, 157b and end effectors 157c, 157d from buffer stations 190a-190d (e.g., by rotating arms 155c, 155d and swinging end effectors 157a, 157b and end effectors 157c, 157d clear of the buffer stations 190a-190d), at which point substrate handling robots 150a, 150b may be ready to begin another substrate transfer process.

While the preceding examples focus on the transfer of substrates 105 between buffer stations 190 and processing tool 160, buffer stations 190 may also facilitate the transfer of substrates 105 (e.g., the simultaneous transfer of multiple substrates 105) between buffer stations 190 and substrate storage modules 142. By way of example, substrate handling robots 150a, 150b may each be able to gather a pair of substrates 105 from storage modules 142 and transfer them to buffer stations 190, and vice versa. In some cases, substrates handling robots 150a, 150b may be used to transfer substrates 105 from a single substrate storage module 142 (e.g., from one of substrate storage modules 142a-142d), for example, in sequentially processing or storing substrates 105 therein. In such cases, substrate handling robots 150a, 150b may operate to exchange substrates 105 between each other, and in some embodiments, for example, may employ a substrate exchange fixture 116 provided within EFEM 110 in order to do so (as previously discussed).

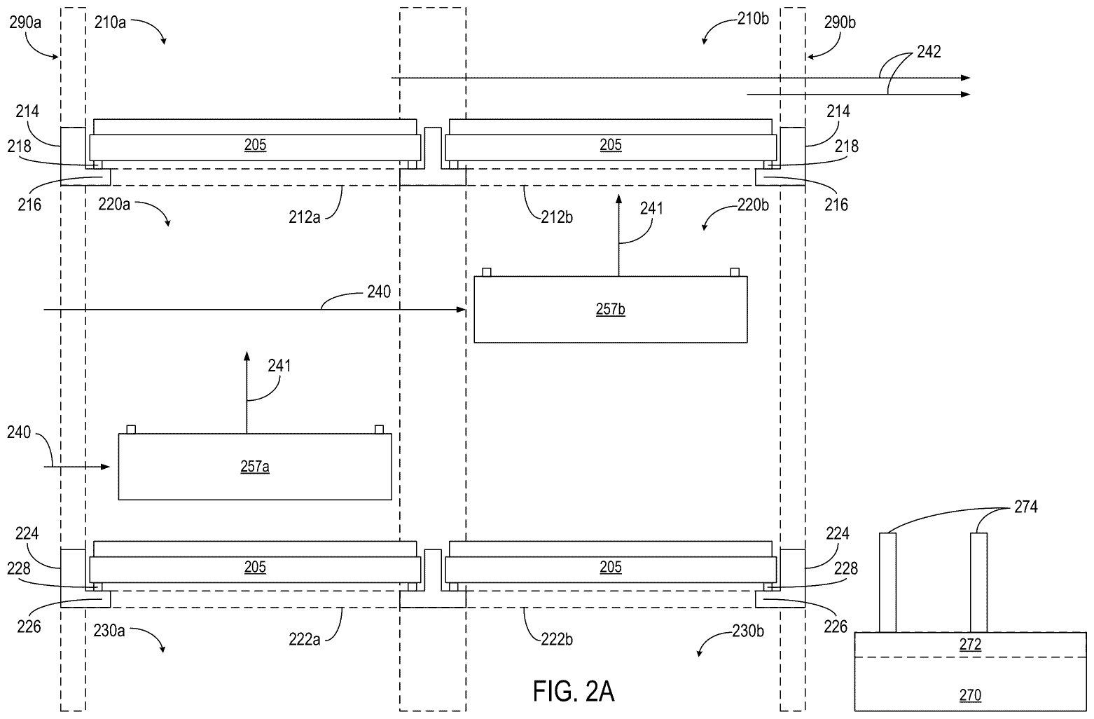

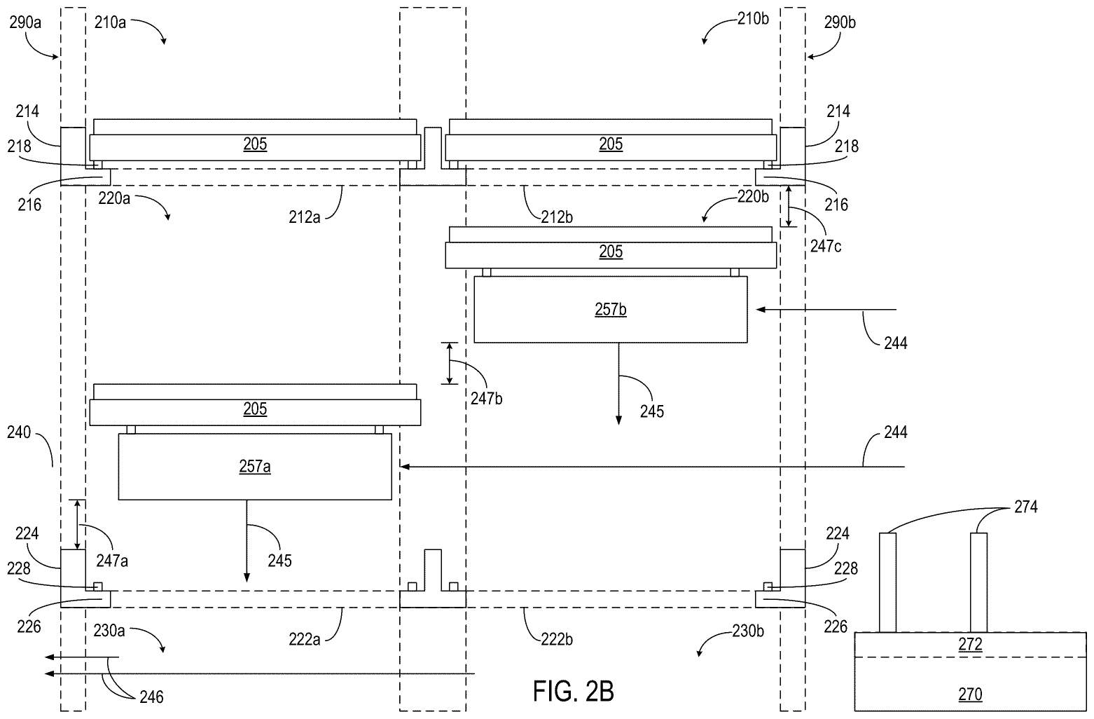

FIGS. 2A-2B (collectively FIG. 2) illustrate a rear cross-sectional view of a portion of a pair of buffer stations 290a, 290b that may be used in an integrated substrate processing system (e.g., as buffer stations 190a, 190b and/or buffer stations 190c, 190d in the integrated substrate processing system 100 of FIG. 1), in accordance with at least one embodiment of the present disclosure. More particularly, in FIG. 2, a pair of parallel slots 210, 220 within buffer stations 290a, 290b (slots 210a, 210b and slots 220a, 220b) are shown, from which a pair of substrates 205 may be gathered and deposited.

Each buffer station 290a, 290b, for example, may include a number of shelves that may be vertically stacked to form a number of slots in which individual substrates 205 may be stored (e.g., before and after processing by a processing tool). Shelves 212a, 222a of buffer station 190a and shelves 212b, 222b of buffer station 290b, for example, may be vertically stacked to form slots 210a, 220a, and slots 210b, 220b in which substrates 205 may be stored. For example, as illustrated in FIG. 2, shelves 212, 222 may comprise a vertical wall 214, 224 and lips 216, 226 extending from a bottom portion thereof that may form a pocket in which substrates 205 may rest. In some embodiments, pads 218, 228 may be provided on an upper surface of lips 216, 226 that may interface with substrates 205.

Buffer stations 290a, 290b may be designed to allow substrate handling robots (e.g., substrate handling robots 150 of FIG. 1) to transfer substrates 205 therefrom and thereto. A substrate handling robot 150, for instance, may be able to access slots 210, 220 to gather or deposit substrates 205 therefrom or thereto. The shelves 212, 222, for example, may be shaped so as to provide a central channel through which end effectors of the substrate handling robot (e.g., as illustrated, end effectors 257a, 257b) may be able to pass through (e.g., to into and out of the buffer stations 290 and between slots 210, 220 thereof).

Buffer stations 290 may be designed to facilitate the simultaneous transfer of substrates 205 therefrom and thereto (e.g., to and from slots 210, 220 thereof). By way of example, a substrate handling robot may be able to simultaneously gather a pair of substrates 205 from slots 210a, 210b. As illustrated in FIG. 2A, for example, a substrate handling robot may position end effectors 257a, 257b below slots 210a, 210b, within slots 220a, 220b, in alignment with a central channel thereof. For example, as illustrated in FIG. 2A, the substrate handling robot may swing (as depicted by arrows 240) end effectors 257a, 257b into place within slots 220a, 220b from an initial position (not shown) adjacent to the buffer stations 290a, 290b. The slot pitch of slots 220a, 220b, for instance, may provide sufficient space for end effectors 257a, 257b to enter into and be accommodated within slots 220a, 220b (e.g., above shelves 222, even with substrates 205 resting thereon). The substrate handling robot may then raise (as depicted by arrows 241) end effectors 257a, 257b to gather substrates 205 from each target slot 210a, 210b. The end effectors 257a, 257b, for example, may enter into the target slots 210a, 210b and lift the substrates 205 off of shelves 210a, 210b thereof. The substrate handling robots may then move end effectors 257a, 257b and substrates 205 thereon into position over stage 270 (e.g., over corresponding sets of lift pins 274, which may be in a fully extended position above a surface of chuck 272 of stage 270). In some embodiments, the buffer stations 290a-290b may be positioned at generally the same height as the processing stage 270 such that the target slots 210a, 210b may be at a higher level than the stage 270 and extended lift pins 274, allowing end effectors 257a, 257b to be swung (as depicted by arrows 242) into place above stage 270.

As another example, a substrate handling robot may be able to simultaneously deposit a pair of substrates 205 into slots 220a, 220b. As illustrated in FIG. 2B, for example, a substrate handling robot may move end effectors 257a, 257b, having substrates 205 resting thereon, within target slots 220a, 220b in alignment with a central channel thereof. For example, as illustrated in FIG. 2B, the substrate handling robot may swing (as depicted by arrows 244) end effectors 257a, 257b into place within slots 220a, 220b from an initial position adjacent to the buffer stations 290a, 290b. In some embodiments, the buffer stations 290a-290b may be positioned at generally the same height as the processing stage 270 (e.g., with extended lift pins 274 at a higher level than shelves 222a, 222b) allowing end effectors 257a, 257b to be swung into place within slots 220a, 220b. The slot pitch of slots 220a, 220b may provide sufficient space for end effectors 257a, 257b to enter into and be accommodated within slots 220a, 220b. The slot pitch, for example, may allow for adequate clearance 247 to be provided between end effector 257a (and substrate 205 thereon) and shelf 222a (e.g., clearance 247a), between end effector 257a (and substrate 205 thereon) and end effector 257b (e.g., clearance 247b), and between end effector 257b (and substrate 205 thereon) and shelf 212b (e.g., clearance 247c). Once in position within the target slots 220a, 220b, the substrate handling robot may lower (as depicted by arrows 245) end effectors 257a, 257b to deposit substrates 105 into each target slot 220a, 220b. The end effectors 257a, 257b, for example, may enter into adjacent slots 230a, 230b, below the target slots 220a, 220b and place the substrates 205 onto shelves 220a, 220b. The substrate handling robot may then remove the end effectors 257a, 257b from buffer stations 290a, 290b, for example, by swinging them (as depicted by arrows 246) out of slots 230a, 230b and clear of buffer stations 290a, 290b.

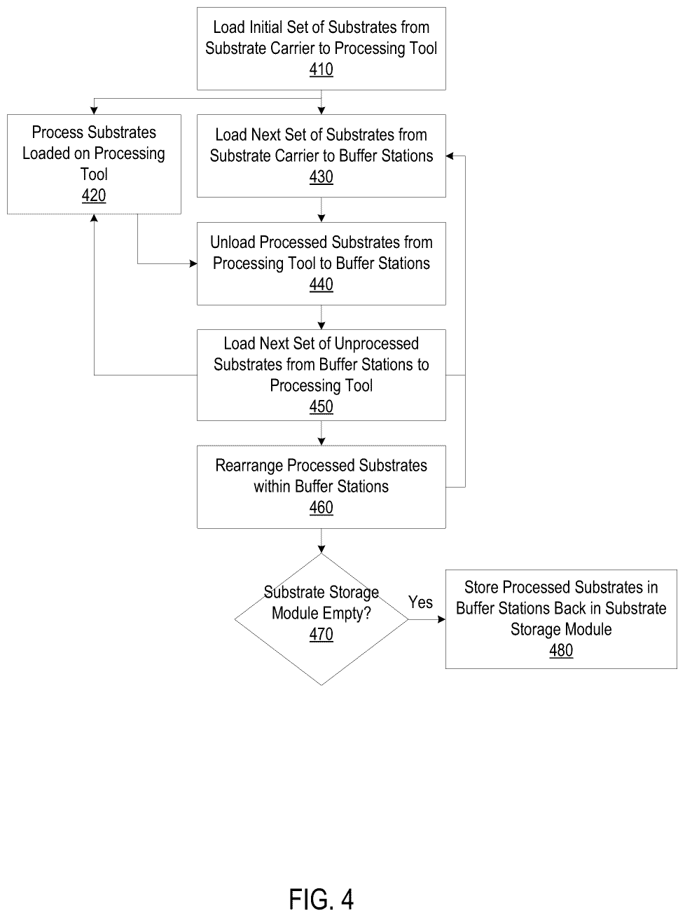

FIG. 4 illustrates a flow diagram of an example method 400 for processing substrates using an integrated substrate processing system in accordance with at least one embodiment of the present disclosure. For the sake of simplicity and clarity, the method is depicted and described as a series of operations. However, in accordance with the present disclosure, such operations may be performed in other orders and/or concurrently, and with other operations not presented or described herein. Furthermore, not all illustrated operations may be performed in implementing methods in accordance with the present disclosure. Those of skill in the art will also understand and appreciate that the methods could be represented as a series of interrelated states or events via a state diagram. Additionally, the disclosed methods are capable of being stored on an article of manufacture. The term “article of manufacture,” as used herein, is intended to encompass a computer-readable device or storage media provided with a computer program and/or executable instructions that, when executed, affect one or more operations. The method 400 (or portions thereof) may be performed by processing logic of a computing device (e.g., by one or more controllers of the integrated substrate processing system 100 of FIG. 1).

At operation 410, an initial set of substrates may be loaded from a substrate carrier (e.g., coupled to an EFEM) onto the stage of a processing tool (e.g., provided within a processing tool enclosure) for processing. At operation 412, for example, the processing tool may be placed into position to receive and secure an initial set of four unprocessed substrates for processing. A stage of the processing tool, for example, may be moved into a home position (or load/unload position), and a plurality of lift pins may be raised above a chuck thereof (e.g., above four different regions of the chuck). At operation 414, one or more substrate handling robots (e.g., provided within the EFEM) may gather the unprocessed substrates from the substrate carrier (e.g., through an opening between the EFEM and substrate carrier) and place them on the stage (e.g., on corresponding extended lift pins). A pair of substrate handling robots, for example, may be used to gather four unprocessed substrates from an initial substrate storage module of the substrate carrier. The substrate storage module, for instance, may store twenty-five substrates in individual slots therein (e.g., for reference, from top to bottom, slot 1 through slot 25), and the substrate handling robots may gather substrates from the bottom-most slots (e.g., slots 22 through 25). In some cases, the initial substrate storage module may not be directly accessibly by one of the substrate handling robots. In such cases, a first robot may gather a pair of substrates from the initial substrate storage module and exchange them with the second substrate handling robot (e.g., using a substrate exchange fixture provided in the EFEM). The substrate handling robots may then move the substrates (e.g., through an opening between the EFEM and processing tool enclosure) into position over the stage of the processing tool. The pair of substrate handling robots, for example, may each move two substrates into position over corresponding sets of extended lift pins (e.g., extending above the stage and a chuck thereof). The substrate handling robots may deposit the substrates onto the extended lift pins, after which the lift pins may be lowered to place the substrates onto the stage and the substrates may be secured thereto (e.g., using a vacuum chucking mechanism of the processing tool). Upon completion of operation 410, the method 400 may proceed to operation 420 and operation 430.

At operation 420, the substrates loaded onto the processing tool may then undergo processing. The stage, for example, may be moved into a processing position under a processing apparatus of the processing tool. The processing apparatus may include one or more processing units that may be used to process (e.g., perform a photolithography process on) the substrates secured to the stage.

At operation 430, a next set of unprocessed substrates may be loaded from the substrate carrier into one or more buffer stations (e.g., provided within the processing tool enclosure). For example, upon completion of operation 410 and while processing of substrates at operation 420 is ongoing (e.g., during processing of an initial set of substrates), a set of four additional unprocessed substrates may be loaded from a substrate carrier into the buffer stations, where the unprocessed substrates may be staged until the processing tool is ready to receive and process them. One or more substrate handling robots, for instance, may be used to gather the unprocessed substrates from the substrate carrier. A pair of substrate handling robots, for example, may be used to gather four more unprocessed substrates from the initial substrate storage module of the substrate carrier. The pair of substrate handling robots, for instance, may gather the next four unprocessed substrates (e.g., from the bottom-most slots) of the substrate storage module used in operation 414 (e.g., from slots 18 through slots 21 thereof), with the substrate handling robots exchanging substrates as necessary (e.g., in cases where the substrate storage module is not directly accessible by one of the substrate handling robots). Once gathered, the substrate handling robots may move the substrates (e.g., through an opening between the EFEM and processing tool enclosure) into position to be deposited into the buffer stations. The pair of substrate handling robots, for example, may move the four unprocessed substrates into position above target slots within four buffer stations. The four buffer stations, for example, may be arranged as two sets of adjacent buffer stations, which in some cases may be formed as a unitary structure, such that each substrate handling robot may position a pair of substrates within parallel slots of adjacent buffer stations. Each buffer station, for instance, may be able to stage nine substrates in individual slots therein (e.g., for reference, from top to bottom, slot 1 through slot 9), and the substrate handling robots may move the substrates into position above a particular target slot (e.g., slot 4) of each buffer station. Once in position, the substrate handling robots may deposit the substrates into the buffer stations. The pair of substrate handling robots, for example, may simultaneously deposit the four unprocessed substrates into respective slots of the four different buffer stations (e.g., into slot 4 of each buffer station).

At operation 440, a set of processed substrates may be unloaded from the processing tool into one or more buffer stations. For example, once processing of substrates at operation 420 is complete, a set of four processed substrates may be unloaded from the processing tool and placed in four buffer stations, where processed substrates may be staged until the processed substrates can be transferred back to the substrate carrier. The processed substrates, for instance, may be staged in the buffer stations until all substrates within the initial substrate storage module are processed, so that the processed substrates may be sequentially placed back in the substrate storage module (e.g., at operation 470). At operation 442, for example, the processing tool may be placed into position to unload the processed substrates. A stage of the processing tool, for instance, may be returned to a home position (from a processing position), and a plurality of lift pins may be raised to lift the processed substrates off of a chuck thereof. At operation 444, a pair of substrate handling robots may be used to gather the processed substrates from the processing tool and deposit them into corresponding buffer stations. A pair of substrate handling robots, for example, may be used to gather the four processed substrates off of the extended lift pins on which the processed substrates may rest. The substrate handling robots may then move the substrates into position to be deposited into corresponding buffer stations. The pair of substrate handling robots, for example, may move the four processed substrates into position above target slots within four buffer stations. The buffer stations, for instance, may be arranged as two set of adjacent buffer stations, and each substrate handling robot may position a pair of substrates within parallel slots of adjacent buffer stations (e.g., into position above slot 3). In some cases, the buffer stations may be positioned at generally the same height as the processing stage, such that the processed substrates can be moved into position in a relatively simply motion. Once in position within the target slots, the substrate handling robots may lower the processed substrates into place. The pair of substrate handling robots, for example, may simultaneously deposit the four processed substrates into respective slots of the four different buffer stations (e.g., into slot 3 of each buffer station).

At operation 450, a next set of unprocessed substrates may be loaded from the buffer stations onto the stage of the processing tool for processing. One or more substrate handling robots, for example, may be used to gather unprocessed substrates previously loaded into and staged in the buffer stations at operation 430 (e.g., in a previous iteration thereof). A pair of substrate handling robots, for instance, may be used to simultaneously gather four unprocessed substrates from the buffer stations (e.g., from slot 4 of each of four buffer stations). The substrate handling robots may then move the substrates into position over the stage of the processing tool (e.g., over corresponding sets of lift pins extended above a chuck thereof). Once in position, the substrates handling robots may deposit the substrates onto the extended lift pins, after which the lift pins may be lowered to place the substrates onto a surface of the chuck and the substrates may be secured thereto (e.g., using a vacuum chucking mechanism of the processing tool).

Upon completion of operation 450, the method 400 may return to operation 420, where processing of the substrates loaded onto the processing tool may begin, and operation 430, where a next set of unprocessed substrates may be loaded from the substrate carrier into the buffer stations at operation 430. The substrate handling robots, for example, may gather the next four unprocessed substrates (e.g., from the bottom-most slots) of the initial substrate storage module used in a previous iteration of operation 430 (e.g., from slots 14 through slots 17), and store them in the buffer stations (e.g., in a particular slot thereof). In some cases, the substrates may be stored in the same slot within the buffer stations across processing iterations (e.g., slot 4 of each buffer station). Substrate handling robots may perform the same movements in loading unprocessed substrates from the buffer stations to the processing tool (e.g., at operation 450). In some cases, the slot may be chosen so as to simplify the movement of the substrate handling robot (e.g., to minimize an amount of, or eliminate the need for, adjustment of a position of the substrates in a vertical dimension), allowing for the more efficient (e.g., faster) transfer of substrates from the buffer stations to the processing tool.

In some cases, before returning to operation 430 and while processing of substrates at operation 420 is ongoing, method 400 may proceed to operation 460, wherein the substrate handling robots may rearrange the processed substrates staged within the buffer stations. The substrate handling robots, for example, may move the processed substrates transferred from the processing tool to the buffer stations at operation 440 (e.g., to slot 3 thereof) to another slot, so that the slot may be available to receive a next set of processed substrates (e.g., after processing at operation 420 has completed). The substrate handling robots may perform the same movements in unloading processed substrates from the processing tool to the buffer stations (e.g., at operation 440). In some cases, the slot may be chosen so as to simplify the movement of the substrate handling robot (e.g., to minimize an amount of, or eliminate the need for, adjustment of a position of the substrates in a vertical dimension), allowing for the more efficient (e.g., faster) transfer of substrates from the processing tool to the buffer stations. The substrate handling robots, for instance, may move the processed substrates within a particular slot (e.g., within slot 3) of the buffer stations to a highest available slot of the buffer stations (e.g., excluding the particular slot in which unprocessed substrates are staged for transfer to the processing tool).

Once processing is complete at operation 420, the processed substrates may be unloaded from the processing tool into the buffer stations at operation 440. The pair of substrate handling robots, for example, may unload the four processed substrates into the buffer stations (e.g., into slot 3 of each buffer station, which may be available after operation 460). A next set of unprocessed substrates may be loaded from the buffer stations onto the stage of the processing tool for processing at operation 450. The pair of substrate handling robots, for example, may load four more unprocessed substrates from the buffer stations (e.g., from slot 4 of each of four buffer stations).

Operations 420-460 may be repeated until all substrates within the initial substrate storage module have been loaded for processing, at which point processing may continue with the next substrate storage module in the substrate carrier. By way of example, in a sixth iteration of operation 430, the substrate handling robots may load a final substrate of the initial substrate storage module (e.g., from slot 1 thereof) and three additional substrates from the next storage module (e.g., from slots 23 through slots 25 thereof) for processing. Additionally, once processing of the final substrate of the initial storage module is complete (e.g., in a seventh iteration of operation 420) and unloaded from the processing tool (e.g., in a seventh iteration of operation 440), the processed substrates staged within the buffer stations may be stored back in the initial substrate storage module.

For example, in some cases, upon completion of operation 460 a determination may be made whether a substrate storage module is empty at operation 470. If the substrate storage module is empty, operation 480 may be initiated. For example, while processing of substrates at operation 420 is ongoing (e.g., during processing of substrates from the next substrate storage module), a pair of substrate handling robots may be used to gather processed substrates (e.g., a pair of processed substrates from each set of adjacent buffer stations) and deposit them into the substrate storage module (e.g., from top to bottom), with the substrate handling robots exchanging substrates as necessary (e.g., in cases where the substrate storage module is not directly accessible by one of the substrate handling robots). In some embodiments, the substrate handling robots may store the substrates back in the substrate storage module in the same order in which the substrates were processed (e.g., last-in first-out). The substrate handling robots may repeat the process until all processed substrates from the initial substrate storage module have been stored back in the initial substrate storage module. By way of example, the substrate handling robots may first transfer the final substrate (e.g., back into slot 1 of the initial substrate storage module), followed by the next four substrates (e.g., into slots 2 through slots 5), and so on, until all twenty-five substrates have been stored back into the initial substrate storage module. In some embodiments, operation 480 may be performed in parallel to operations 420-460, so as to minimize the amount of processing downtime. By way of example, once a next set of substrates has been loaded to the processing tool (e.g., substrates from slots 19 through slots 22 of the next substrate storage module), operation 480 may begin. By way of example, the substrate handling robots may operate to transfer some of the substrates (e.g., a final substrate followed by four additional substrates) back to the initial substrate storage module, before the substrate handling robots may be needed to perform operations 430-450, whereafter operation 480 may resume. Operations 420-480 may be repeated until all substrates within all substrate storage modules of the substrate carrier have been processed and stored back therein.

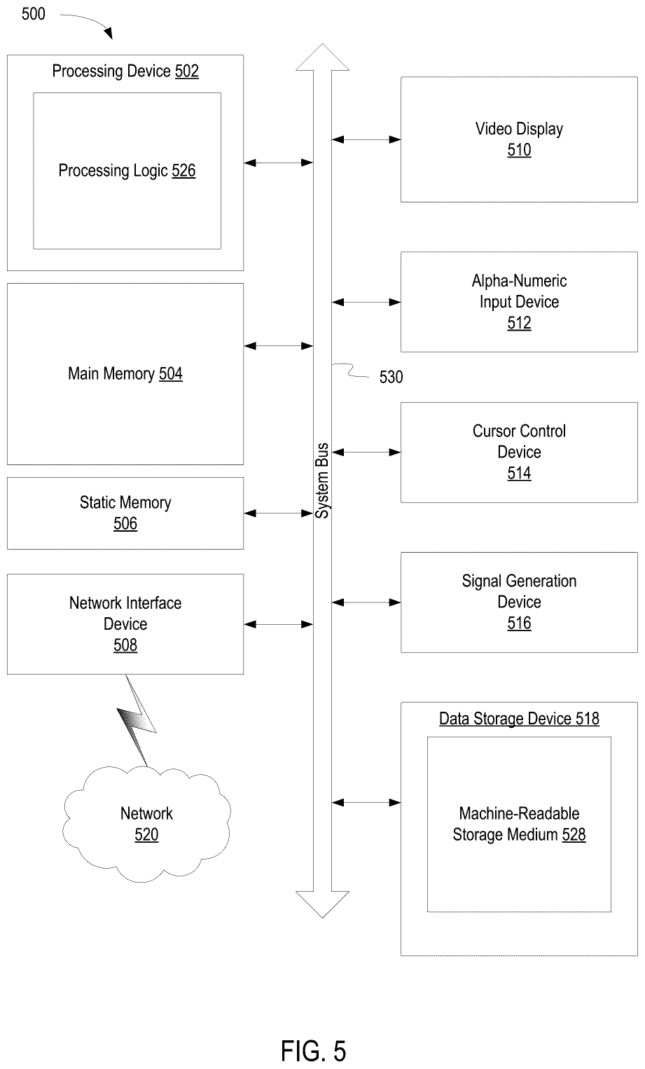

FIG. 5 illustrates a block diagram of an example computer system 500 in accordance with at least one embodiment of the present disclosure. The computer system 500 may include a set of executable instructions to perform one or more of the methodologies discussed herein. In one embodiment, for example, the computer system 500 may include instructions to enable execution of the processes and affect operation of corresponding components shown and described in connection with FIGS. 1-4.

In alternative embodiments, the systems may include a machine connected (e.g., networked) to other machines in a LAN, an intranet, an extranet, or the Internet. The machine may operate in the capacity of a server machine in client-server network environment. The machine may be a personal computer (PC), a neural computer, a set-top box (STB), Personal Digital Assistant (PDA), a cellular telephone, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies described herein.

The example computer system 500 can include a processing device (processor) 502, a main memory 504 (e.g., read-only memory (ROM), flash memory, dynamic random access memory (DRAM) such as synchronous DRAM (SDRAM)), a static memory 506 (e.g., flash memory, static random access memory (SRAM)), and a data object storage device 518, which communicate with each other via a bus 530.

Processing device 502 represents one or more general-purpose processing devices such as a microprocessor, central processing unit, or the like. More particularly, the processing device 502 may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 502 may also be one or more special-purpose processing devices such as an application specific integrated circuit (ASIC), a field programmable gate array (FPGA), a digital signal processor (DSP), network processor, or the like. In various embodiments of the present disclosure, the processing device 502 is configured to execute instructions for the devices or systems described herein for performing the operations and processes described herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The data storage device 518 may include a computer-readable medium 528 on which is stored one or more sets of instructions of the devices and systems as described herein embodying any one or more of the methodologies or functions described herein. The instructions may also reside, completely or at least partially, within the main memory 504 and/or within processing logic 526 of the processing device 502 during execution thereof by the computer system 500, the main memory 504 and the processing device 502 also constituting computer-readable media.

The instructions may further be transmitted or received over a network 520 via the network interface device 508. While the computer-readable storage medium 528 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing, encoding or carrying a set of instructions for execution by the machine and that cause the machine to perform any one or more of the methodologies of the present disclosure. The term “computer-readable storage medium” shall accordingly be taken to include, but not be limited to, solid-state memories, optical media, and magnetic media.

The preceding description sets forth numerous specific details such as examples of specific systems, components, methods, and so forth, in order to provide a good understanding of several embodiments of the present disclosure. One skilled in the art, however, will appreciate that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout the specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout the specification are not necessarily all referring to the same embodiment. In addition, the term “or” is intended to mean an inclusive “or” rather than an exclusive “or.” When the term “about” or “approximately” is used herein, the term is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. The term can also be expressed as “about 10 or more.” Similarly, the term “less than about” typically includes the recited number plus 10% and any quantity that is lower such that “less than about 10” would include 11 and anything less than 11. The term can also be expressed as “about 10 or less.”

Recitation of ranges of values herein are merely intended to serve as a shorthand method of referring individually to each separate value falling within the range, unless otherwise indicated herein, and each separate value is incorporated into the specification as if the value were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
an equipment front end module (EFEM) and a processing tool enclosure, wherein the EFEM and processing tool enclosure are coupled together to form an integrated processing environment.

2. The system of claim 1, wherein the integrated processing environment is maintained at substantially uniform conditions throughout.

3. The system of claim 1, wherein the integrated processing environment is maintained at a temperature of between 21 and 25 degrees Celsius, within 0.05 degrees Celsius, and a relative humidity of between 45-55 percent.

4. The system of claim 1, further comprising:
a remote air module (RAM) coupled to the EFEM and processing tool enclosure to supply air to the EFEM and processing tool enclosure at a particular temperature and relative humidity.

5. The system of claim 4, wherein air is exhausted from the EFEM and processing tool enclosure to the RAM.

6. The system of claim 5, wherein air is exhausted from the EFEM to the RAM indirectly through the processing tool enclosure.

7. The system of claim 1, further comprising:
one or more substrate handling robots to transfer substrates through one or more openings in the EFEM and processing tool enclosure without disturbing the integrated processing environment.

8. A system comprising:
a processing tool comprising a movable stage;
one or more buffer stations positioned near the movable stage; and
one or more substrate handling robots to transfer substrates between the one or more buffer stations and the movable stage.

9. The system of claim 8, wherein each robot of the one or more substrate handling robots is to transfer a plurality of processed substrates from the movable stage to the one or more buffer stations and transfer a plurality of unprocessed substrates from the one or more buffer stations to the movable stage in less than 10 seconds.

10. The system of claim 8, wherein each robot of the one or more substrate handling robots is to transfer a plurality of substrates to or from the one or more buffer stations in a single movement.

11. The system of claim 8, wherein the one or more substrate handling robots are to transfer substrates between one or more substrate storage modules and the one or more buffer stations or the movable stage.

12. The system of claim 8, wherein each of the one or more substrate handling robots comprises:
a plurality of end effectors coupled to an articulating linkage, wherein the articulating linkage comprises one or more direct drive motors to affect movement of the plurality of end effectors, each of the plurality of end effectors to handle an individual substrate.

13. The system of claim 12, wherein a friction grip is provided on a surface of each of the plurality of end effectors to secure the individual substrate during movement of the plurality of end effectors.

14. The system of claim 13, wherein the friction grip on the surface of each of the plurality of end effectors is to secure the individual substrate with up to 2 mm of warpage at up to 1 G of force.

15. A method comprising:
transferring, by each of one or more substrate handling robots, a plurality of processed substrates from a movable stage of a processing tool to a plurality of buffer stations positioned near the movable stage;
transferring, by each of the one or more substrate handling robots, a plurality of unprocessed substrates from the plurality of buffer stations to the movable stage; and
performing a photolithography process on the plurality of unprocessed substrates with the processing tool.

16. The method of claim 15, further comprising:
transferring, by each of the one or more substrate handling robots, an initial plurality of unprocessed substrates from a substrate storage module to the movable stage.

17. The method of claim 16, further comprising:
exchanging the initial plurality of unprocessed substrates between two of the one or more substrate handling robots.

18. The method of claim 15, further comprising:
transferring, by each of the one or more substrate handling robots, another plurality of unprocessed substrates from a substrate storage module to the plurality of buffer stations.

19. The method of claim 18, wherein the one or more substrate handling robots transfer the another plurality of unprocessed substrates from the substrate storage module to the plurality of buffer stations while the processing tool is performing the photolithography process on the plurality of unprocessed substrates.

20. The method of claim 18, further comprising:
transferring, by the one or more substrate handling robots, a plurality of processed substrates from the plurality of buffer stations to the substrate storage module.
